(19) United States
(12) Patent Application Publication
(10) Pub. No.: US 2009/0050905 A1
(43) Pub. Date: Feb. 26, 2009

(54) Highly Efficient Light-Emitting Diode

(76) Inventor: Nayef M. Abu-Ageel, Haverhill, MA (US)

Correspondence Address: MICHAEL K. LINDSEY;GAVRILOVICH, DODD & LINDSEY, LLP, 3303 N. SHOWDOWN PL., TUCSON, AZ, 85749, US

(21) Appl. No.: 12/194,535

(22) Filed: Aug. 19, 2008

Related U.S. Application Data
(60) Provisional application No. 60/956,877, filed on Aug. 20, 2007.

(51) Int. Cl. H01L 33/00; H01L 31/00

(52) U.S. Cl. 257/80; 257/E33.001; 257/E31.001

(57) ABSTRACT

A high extraction efficiency light-emitting diode (LED) capable of producing a light beam of selected cross-section and selected spatial distribution of light in terms of intensity and angle is disclosed. The LED utilizes micro and/or nano optical elements in order to extract more light at one or more specified cone angles.

### CLAIM OF PRIORITY UNDER 35 U.S.C. §119

This application claims the benefit of U.S. Provisional Application No. 60/956,877, filed on Aug. 20, 2007, which is hereby incorporated by reference.

### BACKGROUND

1. Field

The invention relates generally to light-emitting diodes. More particularly, it relates to light-emitting diodes that incorporate micro-optical and nano-optical elements in their structure in order to enhance the extraction efficiency.

2. Background

Light-emitting diodes (LEDs) are considered attractive light sources for various applications such as such as traffic signals, displays, automobile headlights and taillights and conventional indoor lighting. However, only a small portion (˜2%) of light generated within the LED active layer can be extracted and utilized while the remaining part is absorbed within the LED. This is due to the difficulty for light to be extracted from semiconductor materials with high index of refraction. Typical LED semiconductors have index of refraction ranging from 2.2 to 3.8, which is high when compared to that of ambient air (˜1.0).

Many methods for increasing the LED efficiency (i.e., extracting more light from the LED active layer) have been reported. Schnitzer, et al. in “30% External Quantum Efficiency From Surface Textured, Thin Film Light-emitting Diodes”, Applied Physics Letters 63, 1993, pp. 2174-2176, propose a method of introducing random nanotexturing on the LED's surface. Since the introduced features are on the order of the wavelength of light, the light behavior becomes chaotic leading to enhanced LED efficiency.

Other methods introduce periodic or nonperiodic patterns (rather than random texturing) on the order of light wavelength to the emitting surface or internal interfaces of the LED. Due to interference effects, more light is extracted from the LED active layer leading to enhanced efficiency. Examples of this method are discussed in U.S. Pat. No. 5,779,924 to Krames et al. and U.S. Pat. No. 6,831,302 B2 to Erchak et al.

Schnitzer, et al. in “Ultrahigh Spontaneous Emission Quantum Efficiency, 99.7% Internally and 72% Externally, From AlGaAs/GaAs/AlGaAs Double Heterostructures”, Applied Physics Letters 62, 1993, pp. 131-133, propose photon recycling for extracting more light from the LED. This method requires materials with extremely low optical loss and the use of a non-absorbing current spreading layer on the LED surface.

In another approach, Parkyn, Jr. et al. in U.S. Pat. No. 6,560,038 B1 propose the use of light pipes to extract more light from the LED. Krames, et al. in “High Power Truncated Inverted Pyramid (AlₓGa₁₋ₓ)₀.5In₀.5P/GaP Light-emitting Diodes Exhibiting >50% External Quantum Efficiency,” Applied Physics Letters 75, 1999, teach the angling of the LED chip's side surfaces to create an inverted truncated pyramid and thus enhance the extraction efficiency.

In another approach, Illek, et al. in U.S. Patent Publication No. 2004/0084682 A1 propose the introduction of inclined micro-guides in part of the epitaxial layer sequence in order to extract more light from the LED. The proposed micro-guides have the shapes of truncated pyramids or frustums as shown in FIGS. 1B-1D. However, the introduced shapes of the micro-guides have the disadvantages of low extraction efficiency and lack of angular directionality when compared to the micro-guides' shapes of this disclosure as shown in FIGS. 2A-2B.

### SUMMARY

The known methods for enhancing LED light extraction suffer from lack of effective control over the spatial distribution of light in terms of angle and intensity. Therefore, there is a need for an efficient light extraction system that provides effective control over spatial distribution of LED light in terms of intensity and angle.

Disclosed herein are high extraction efficiency light-emitting diodes (LEDs) capable of producing light beams, of selected cross-section and selected spatial distribution of light in terms of intensity and angle. The disclosed LEDs and structures utilize micro and/or nano optical elements in order to extract more light at certain cone angles.

### BRIEF DESCRIPTION OF THE DRAWINGS

It is to be understood that the drawings are solely for purposes of illustration and not as a definition of the limits of the invention. Furthermore, it is to be understood that the drawings are not necessarily drawn to scale and that, unless otherwise stated, they are merely intended to conceptually illustrate the structures and methods described herein.

FIG. 1A shows a cross-sectional view of a light-emitting diode of the prior art utilizing a photonic crystal.

FIGS. 1B-1D show cross-sectional views of various micro-guide shapes of the prior art.

FIGS. 2A-2C show cross-sectional views of various micro-guide shapes of the current disclosure.

FIGS. 2D-2F show cross-sectional views of various micro-guide and micro-lens shapes of the current disclosure.

FIGS. 3-12 show cross-sectional views of various light-emitting diodes of the current disclosure.

### DETAILED DESCRIPTION

The following detailed description, which references to and incorporates the drawings, describes and illustrates one or more specific embodiments. These embodiments, offered not to limit but only to exemplify and teach, are shown and described in sufficient detail to enable those skilled in the art to practice what is claimed. Thus, for the sake of brevity, the description may omit certain information known to those of skill in the art.

The word “exemplary” is used throughout this disclosure to mean “serving as an example, instance, or illustration.” Any embodiment or feature described herein as “exemplary” is not necessarily to be construed as preferred or advantageous over other embodiments or features.

Described herein are LEDs incorporating at least one array of micro and/or nano optical elements.

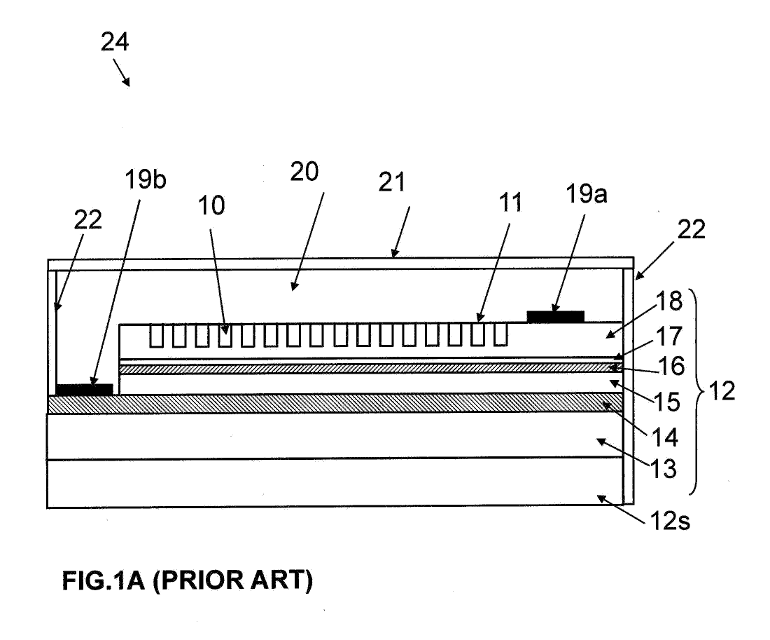

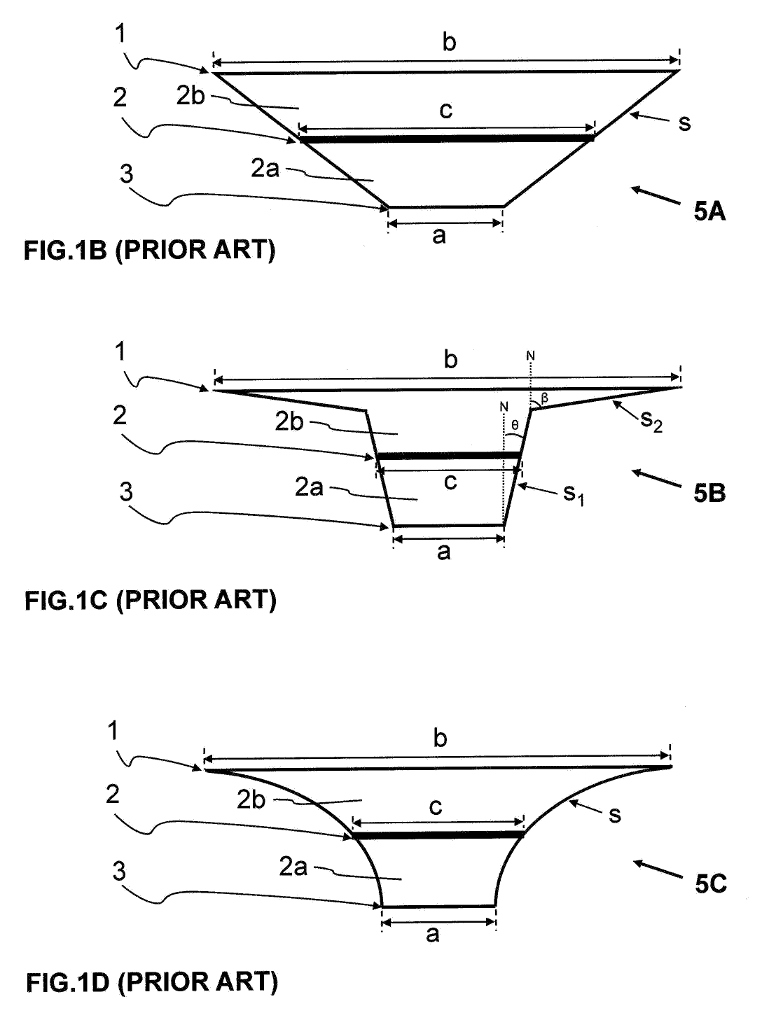

FIG. 1A shows a cross-sectional view of a prior art light-emitting diode (LED) 24 utilizing a photonic crystal 10 (i.e. a lattice of holes formed in the LED structure) as discussed by Erchak et al. in U.S. Pat. No. 6,831,302 B2. LED 24 includes a multi-layer stack 12 disposed on a submount 12s. Multi-layer stack 12 consists of n-doped GaN layer 18 having a pattern of openings 10 in its upper surface 11, a bonding layer 13, a silver layer 14, a p-doped GaN layer 15, active region 16, and a AlGaN layer 17. An n-side contact pad 19a is disposed on layer 18, and a p-side contact pad 19b is disposed on layer 14. An optional encapsulant material (epoxy having an index of refraction of 1.5) 20 is enclosed between layer 18 and a cover slip 21 and supports 22. In this case, optional layer 20 does not extend into openings 10.

Photonic crystal LEDs are also described in U.S. Pat. No. 7,012,279 B2 to Wierer et al., which is incorporated herein by reference.

FIGS. 1B-1D show cross-sectional views of three prior art micro-guide (or micro-reflector) shapes 5A, 5B, and 5C as discussed by Illek, et al. in U.S. Patent Publication 2004/0084682 A1.

Micro-guide 5A of FIG. 1B is in the shape of truncated pyramid with a straight sidewall consisting of one segment s, an upper side 1 having a diameter of size b, a lower side 3 having a diameter of size a, and an active layer 2 having a diameter of size c. The active layer 2 is a light-emitting layer that can be made of, for example, a semiconducting layer of uniform composition, a double heterostructure, or a multiple quantum well (MQM) structure comprising InGaAlP. The active layer 2 is sandwiched between two layers 2a and 2b that can be made of semiconducting materials such as InGaAlP, InAlP, GaP and AlGaAs. Each of the two layers 2a and 2b may consist of confinement and current spreading sub-layers.

Micro-guide 5B of FIG. 1C has a sidewall consisting of two straight segments s₁ and s₂ making angles θ and β, respectively, with the axis N (i.e. axis which is normal to the micro-guide surface) where θ<β. When looking from the outside of micro-guide 5B, the sidewall appears as a segmented concave profile with two segments s₁ and s₂.

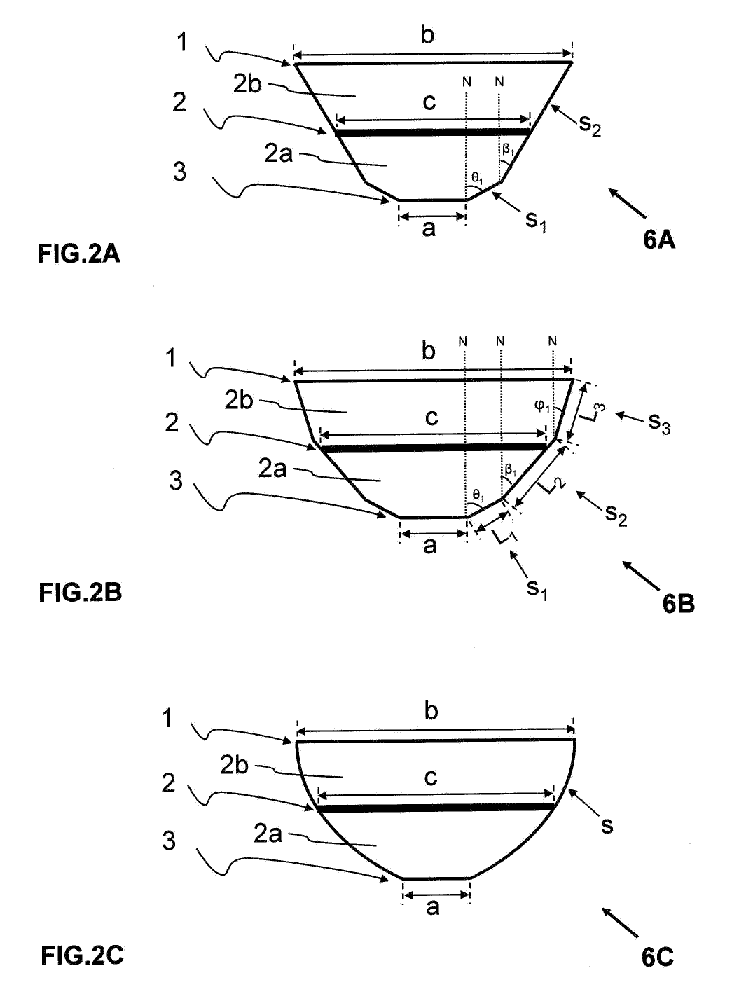

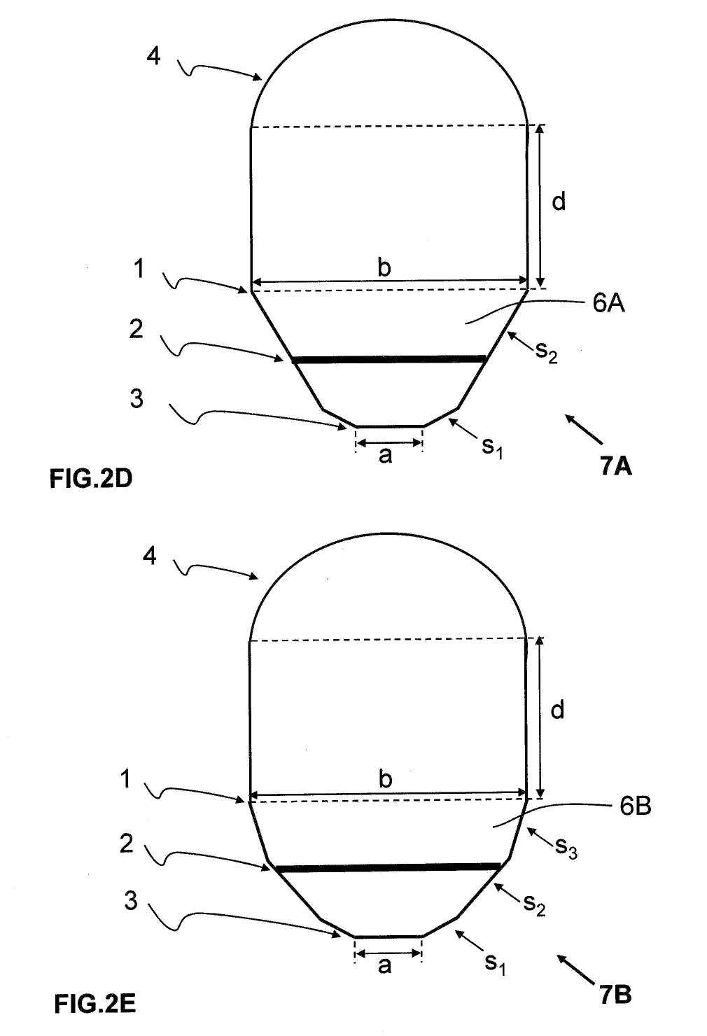

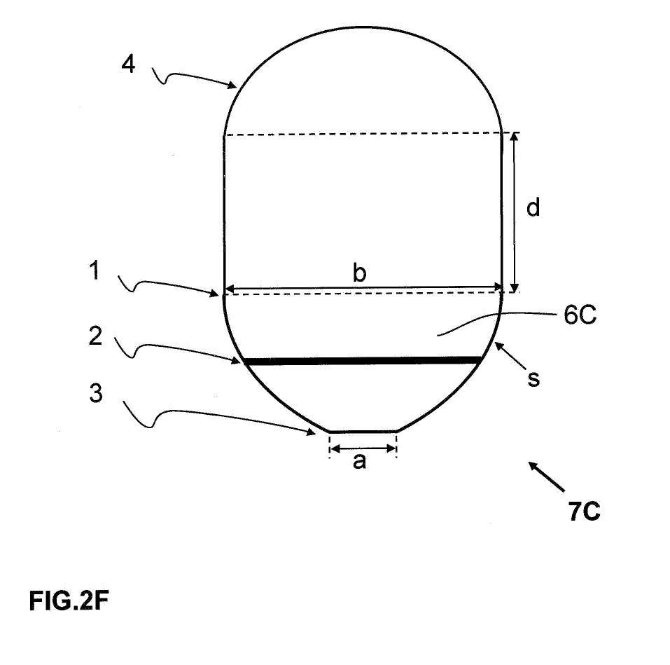

Micro-guide 5C of FIG. 1D has a sidewall consisting of one curved segment s with a concave profile as seen from the outside of the micro-guide 5C. The diameters of the upper side 1, lower side 3 and active layer 2 are as described above for micro-guide 5A of FIG. 1B. Patent Publication 2004/0084682 A1 does not teach the use of micro-guide shapes of having convex shapes as shown in FIGS. 2B-2D, which are more efficient in extracting light from a light-emitting diode (LED) and can deliver more collimated light (i.e., collimated along the axis N). Partially or highly collimated light is more useful than non-collimated light (e.g. Lambertian or isotropic distribution of light) for certain applications such as display applications.

To compare the efficiency of micro-guides of FIGS. 1B-1D and those of FIGS. 2A-2C, a ray tracing simulation was done considering micro-guides with equal diameters of the upper side 1, active layer 2, and lower side 3. During the simulation, location of the active layer 2 within the micro-guide was moved between the lower 3 and upper 1 sides of the micro-guide and its diameter was adjusted accordingly. The reflectivity of the coatings on the micro-guide sidewall were the same in both cases, for example, sidewall coatings with reflectivity of 90% and 95% were assumed in the simulations. The reflectivity of the bottom ohmic contact was assumed to be 30% and the contact sizes were equal in both cases. The diameter of the ohmic contact was assumed to be equal to the diameter of the lower side 3. Optical losses other than those occurring at the sidewall coatings and ohmic contacts were not considered in both cases. The simulation results showed enhanced extraction efficiencies of up to 100% for micro-guides of FIGS. 2A-2C when compared to these for micro-guides of FIGS. 1B-1D. In addition, micro-guides of FIGS. 2A-2C allow for an active layer 2 of a larger size to be included in the LED structure and thus increasing the amount of available light for extraction.

FIG. 2B shows a micro-guide 6B with three straight segments s₁, s₂ and s₃ making angles θ₁, β₁ and φ₁ with the axis N (i.e. the axis normal to the micro-guide 6B surface) where θ₁>β₁>φ₁. The lengths L₁, L₂, L₃ and angles θ₁, β₁ and φ₁ of these segments s₁, s₂ and s₃ can be varied as desired to form a convex sidewall. FIG. 2A shows a micro-guide 6A with a sidewall consisting of two segments s₁ and s₂. FIG. 2C shows a micro-guide 6C having a convex sidewall with a single curved segment s. The shapes of micro-guides of this disclosure are not limited to the two shapes of FIGS. 2A-2C but can be of other shapes having any number of straight and/or curved segments connected with each other to form a complete convex sidewall that extends from the lower diameter to the upper diameter of the micro-guide.

FIGS. 2D-2F show a micro-element 7A, 7B and 7C consisting of a micro-guide 6A, 6B, and 6C and a corresponding micro-lens 4 separated by a distance d. The distance d varies between zero and few millimeters depending on the sizes of the micro-guide 6A, 6B, and 6C and micro-lens 4. The lens 4 can be spherical, aspherical, circular, square, and/or hexagonal and is located at a certain distance d from the top side 1 of the micro-guide 6A, 6B and 6C. The shape (or radius of curvature if lens 4 is spherical) of lens 4 and its location (i.e. distance d) from the top side 1 of the micro-guide 6A, 6B and 6C are selected so that most or all of the light entering the lens 4 exits as a more collimated light. In addition, lens 4 can be optimized in terms of shape and location to increase the amount of extracted light without reducing the cone angle (i.e. no collimation) of delivered light. The micro-guides 5A, 5B and 5C of FIG. 1B-1D can also be combined with a spherical or aspherical lenses as described in connection with FIGS. 2D-2F to increase the amount of extracted light and enhance its directionality (i.e. deliver more collimated light).

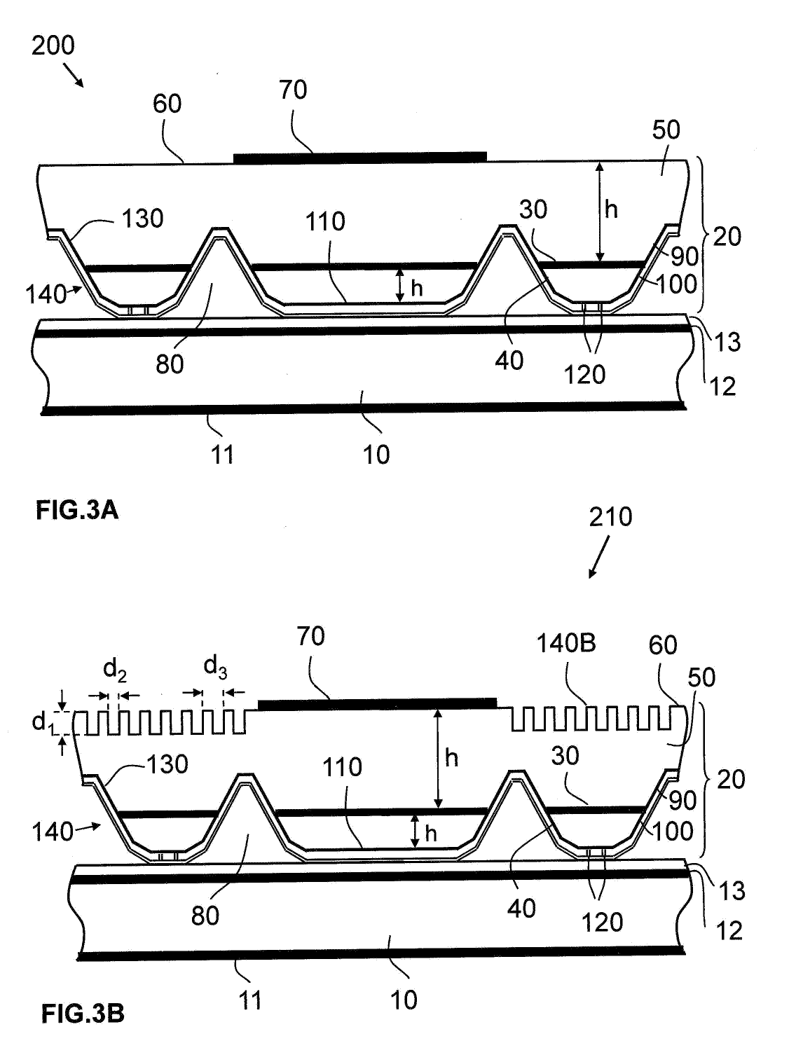

FIG. 3A shows a cross-sectional view of a light-emitting diode 200 that has a carrier 10 bonded to an epitaxial layer 20. The active layer 30 (i.e. the photon-emitting layer) is made at a certain distance h from the base area 110 of the micro-guide. An array of micro-guides 140 (only two are shown) of the type of FIG. 2A is formed in the epitaxial layer 20 as shown in FIG. 3A. Other micro-guide types such as those of FIGS. 2B-2C can be formed in the epitaxial layer 20. No micro-guides are formed under the contact layer 70 in order to avoid light absorption by the contact layer 70. A central electrical contact layer 70 is formed on the front side 60 of the epitaxial layer 20 using an appropriate metallization technique. Adjacent micro-guides 140 are separated by cavities 80. The micro-guides 140 sidewalls are coated with a highly reflective layer that is composed of a dielectric insulating layer (or multiple layers) 90 and a metallization layer 100 applied thereon. The insulating layer 90 contains some openings 120 along base area 110 of the micro-guides 140. Openings 120 are filled with a metallic material in order to form an ohmic contact. FIG. 3B shows a cross-sectional view of a light-emitting diode 210 that has a photonic crystal 140B made in the top surface 60 of epitaxial layer 20. The photonic crystal 140B consists of a modified triangular pattern of openings formed in layer 50 of epitaxial layer 20. The depth, diameter and the spacing between nearest neighbors of openings 140B can vary from tens to thousands of nanometers. Openings 140B can have circular, square, hexagonal, or other cross sections. In some cases, spacing d₃ between nearest neighbors varies between ˜0.1λ and ˜10λ, preferably between about 0.1λ and about 5λ, where λ is the wavelength in the device of light emitted by the active region, depth d₁ of openings 140B varies between zero and the full thickness h of layer 50, and diameter d₂ of openings 140B varies between ˜0.01λ and ˜5λ. Layer 50 is designed to be thick enough to have openings 140B and to spread current and usually has a thickness of ≧0.1 microns. Openings 140B can have a refractive index of one (i.e. representing vacuum or air) or filled with a dielectric material (e.g. silicon oxide) having a refractive index n of more than one. Parameters d₁, d₂, d₃, and n are usually selected to enhance the extraction efficiency from the LED and can be selected to preferentially emit light in a chosen direction.

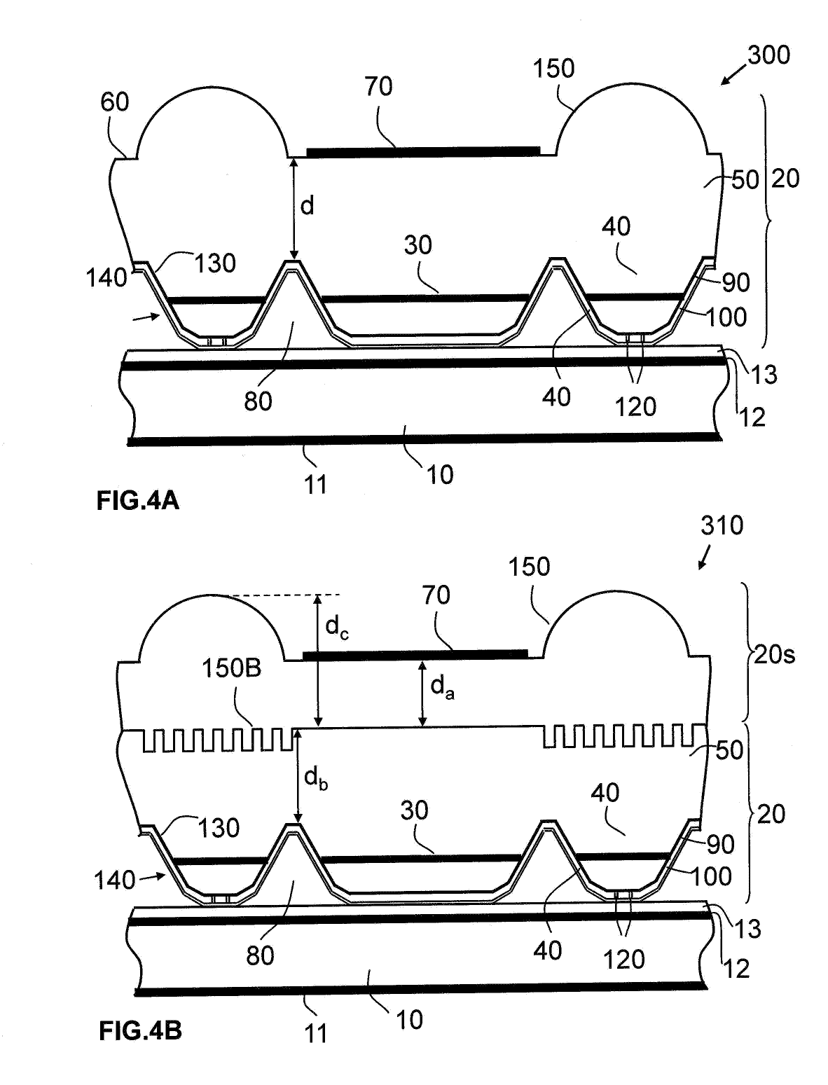

FIG. 4A shows a cross-sectional view of a light-emitting diode 300 that has a micro-lens array 150 and a corresponding micro-guide array 140. Light-emitting diodes 300 and 200 are the same except for the addition of micro-lens array 150 to the structure of light-emitting diode 300. The shape, size and distance d from the micro-guide array of each micro-lens in the micro-lens array 150 can be optimized to extract more light and/or control the cone angle of the extracted light. The micro-guides 40 of light-emitting diode 300 can be formed in other shapes such as those of FIGS. 1B-1D and FIGS. 2A-2C. FIG. 4B shows a cross-sectional view of a light-emitting diode 310 that has a photonic crystal 150B made somewhere between the micro-guide array 140 and micro-lens array 150. In this case, photonic crystal 150B enhances the extraction of light within a certain cone angle and the micro-lens array 150 helps in the further collimation of it. The separations dₐ and d_{b} between the photonic crystal 150B and the micro-lens 150 and micro-guide 140 arrays are selected to enhance light extraction from the LED and/or control cone angle of extracted light. The separations dₐ and d_{b} range between zero and ˜10λ, preferably between about 0.1λ and about 5λ, where λ is the wavelength in the device of light emitted by the active region. It is possible to have the photonic crystal 150B located at a zero distance from the micro-guide 140 array with the openings of the photonic crystal 150B extending partly or completely to the active layer 30.

The manufacturing of light-emitting diodes 200, and 300 starts with growing the epitaxial layer 20 on a base substrate. The epitaxial layer 20 can, for example, be made on the basis of InGaAlP. The epitaxial layer 20 is thereby produced first on a base substrate (not shown in FIGS. 3-4), subsequently, the micro-guides 140 are made into the top side of layer 20 using suitable wet-chemical or dry-chemical etching processes. An insulating layer 90 is then deposited onto the micro-guides 140 sidewalls. This step is followed by the formation of the openings 120 using wet-chemical or dry-chemical etching processes and, subsequently, a metal layer 100 is applied. The micro-guides 140 side is then bonded or attached to a carrier substrate 10 using, for example, eutectic bonding, and the base substrate (not shown in FIGS. 3-4) is removed by wet-etching. Prior to bonding, the carrier substrate 10 (e.g. a GaAs substrate wafer) is coated with two ohmic contact layers 11 and 12 (e.g. AuGe layer) on its back and front sides, respectively, and a bonding layer 13 (e.g. gold-tin solder layer with appropriate diffusion barriers) on top of contact layer 12. After the bonding, the micro-lens array 150 is formed on the top surface 60 of upper layer 50 using suitable wet-chemical or dry-chemical etching processes. The diameters of the micro-guides 140 and micro-lenses 150 are typically in the range of 5-50 μm. The top surface of the upper layer 50 is, subsequently, doped with a concentration above 10¹⁸ cm⁻³ in order to assure that it has a good electrical conductivity. Good conductivity of the upper layer 50 is necessary for spreading current across the LED surface 60. In addition, it is preferable to have an upper layer 50 that is transparent to the light generated in the active layer 30. Subsequently, the contact layer 70 and an optional metal frame that can be used to distribute current across the surface 60 of the upper layer 50 surface more efficiently are formed on the front side of the upper layer 50. Anti-reflective optical coating is then applied to the surface areas of upper layer 50 that are not covered with metal (i.e. contact and frame metallic coatings). Subsequently, the epitaxial layer 20 is divided using chemical or dry etching methods according to the selected chip size and, then, the carrier substrate 10 is divided accordingly by dicing producing chips with the selected size.

The manufacturing process of light-emitting diodes 210 and 310 is the same as the above manufacturing process of light-emitting diodes 200 and 300 up to the bonding step of micro-guide array 140 to carrier substrate 10. After the bonding to carrier substrate 10, the manufacturing process of LED 200 and 300 is different and is described as follows. The photonic crystal 150B is then formed using a wet-chemical or dry-chemical etching processes. In case of LED 300 and once the photonic crystal 140B is formed, doping, deposition of the contact layer 70 and an optional metal frame, dividing the epitaxial layer 20 and dicing carrier substrate 10 are performed as described above for LED 200. In case of LED 310 and once the photonic crystal 150B is formed, a non-patterned substrate 20s (or epitaxial layer grown on top of a substrate) is bonded to the photonic crystal 150B. This substrate 20s is then thinned to the appropriate thickness d_{c} using suitable polishing as well as wet and/or dry etch techniques. This step is followed by the formation of micro-lens array 150 on the top surface of the thinned substrate 20s. Subsequently, doping, deposition of the contact layer 70 and an optional metal frame, dividing the epitaxial layer 20 and dicing carrier substrate 10 are performed as described above for LED 300.

Light-emitting diode (LED) structures disclosed in Patent Publication 2004/0084682 A1 can also be made using micro-guides of FIGS. 1B-1D combined with micro-lens and/or photonic crystal arrays of this disclosure. In addition, LED structures disclosed in Patent Publication 2004/0084682 A1, which is hereby incorporated by reference, can also be made using convex micro-guides that are optionally combined with the micro-lens and photonic crystal arrays of this disclosure. Furthermore, operation and manufacturing methods of LEDs disclosed in Patent Publication 2004/0084682 A1 apply to LEDs based on the convex micro-guide arrays of this disclosure.

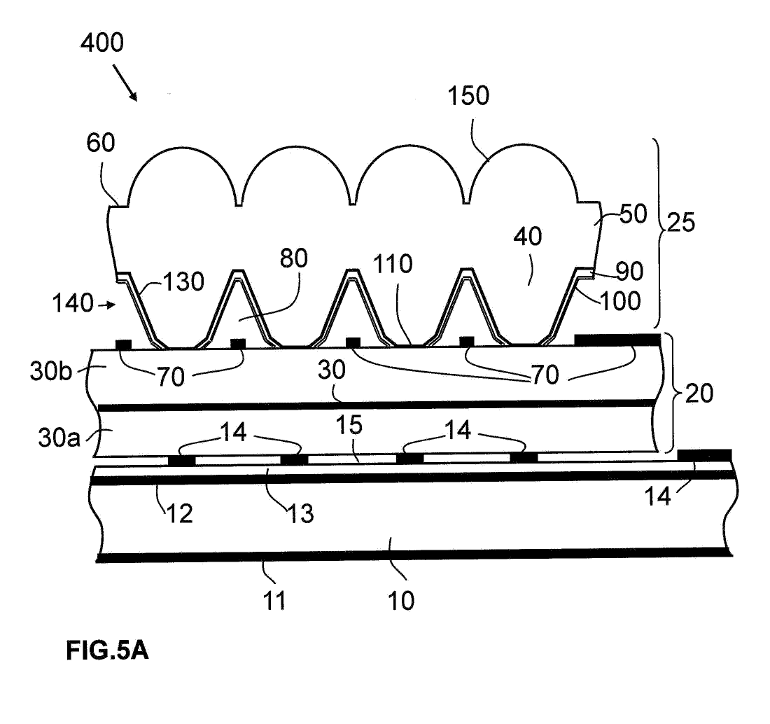

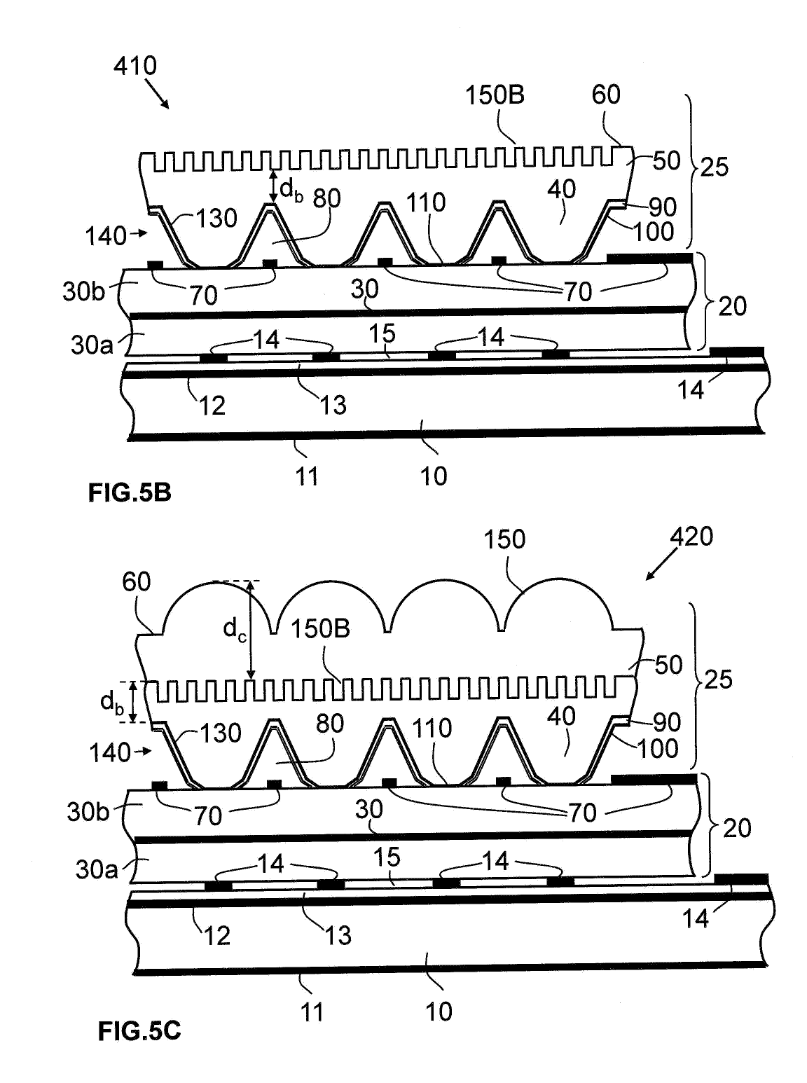

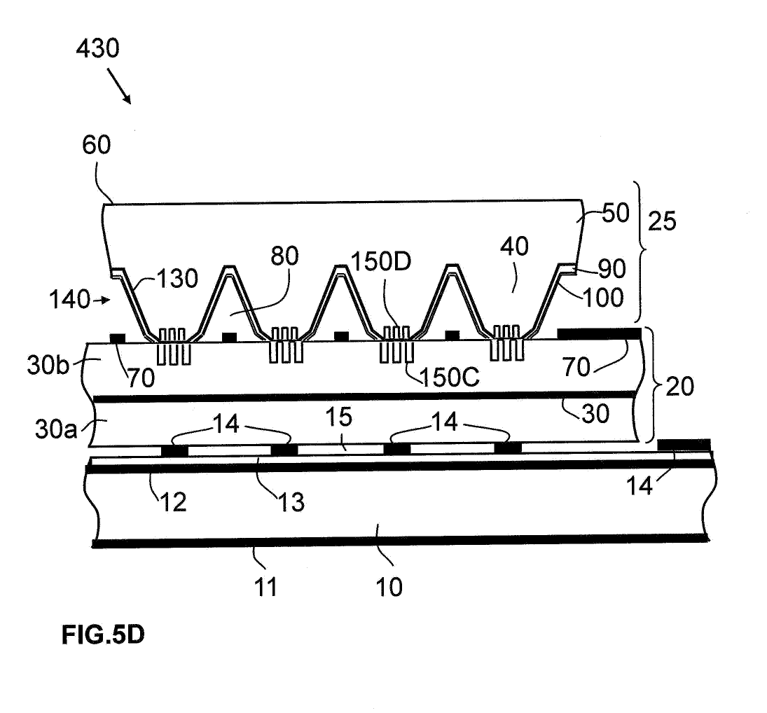

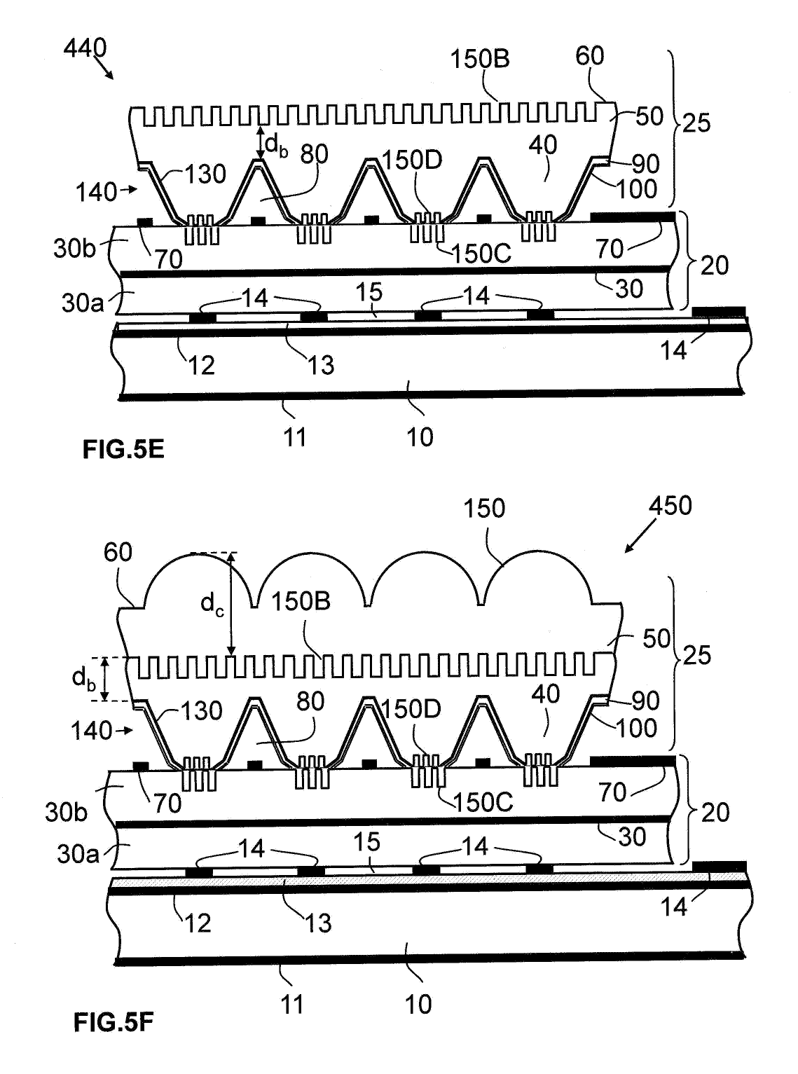

FIG. 5A shows a cross-sectional view of a light-emitting diode 400 that utilizes a micro-element plate 25 for light extraction and a top electrode 70 located directly on top of epitaxial layer 20. Micro-element plate 25 consists of a micro-guide array 140 and a corresponding micro-lens array 150. The epitaxial layer 25 consists of an active layer 30 sandwiched between two layers 30a and 30b, which in turn may consist of confinement and current spreading sub-layers made of appropriate semiconducting materials. The micro-element plate 25 is bonded directly to the epitaxial layer 20 using a suitable semiconductor-to-semiconductor wafer bonding technique to form an optically transparent interface. Since the top electrode 70 is not located on top of the micro-element plate 25, the interface 110 between plate 25 and epitaxial layer 20 does not have to be electrically conducting. The top electrode 70 may occupy a small portion of the surface area of epitaxial layer 20 and can be patterned as desired in the area surrounding the interface 110. The bottom electrode 14 can be patterned on the top surface of carrier substrate 10 so that the electrical current that flows between top 70 and bottom 14 electrodes has the desired distribution within the epitaxial layer 20.

FIG. 5B shows a cross-sectional view of a light-emitting diode 410 that utilizes a photonic crystal 150B combined with a micro-guide array 140 at its top surface. Photonic crystal 150B is formed at a selected distance d_{b} above the micro-guide array 140. This distance d_{b} ranges between zero and ˜10λ, preferably between about 0.1λ and about 5λ. FIG. 5C shows a cross-sectional view of a light-emitting diode 420 that utilizes a photonic crystal 150B combined with a micro-guide array 140 and a micro-lens array 150 at its top surface. Photonic crystal 150B is formed at a selected distance d_{b} above the micro-guide array 140 and d_{c} below the micro-lens array 150. Parameters d_{c} and d_{b} range between zero and ˜10λ, preferably between about 0.1λ and about 5λ. FIG. 5D shows a cross-sectional view of a light-emitting diode 430 that utilizes a photonic crystal 150C within layer 30b at the input apertures of the micro-guides of micro-guide array 140 and another optional photonic crystal 150D within the input apertures of the micro-guides of micro-guide array 140. FIG. 5E shows a cross-sectional view of light-emitting diode 440 that utilizes photonic crystals 150C and 150D as well as a photonic crystal 150B at the exit aperture of micro-guide array 140. FIG. 5F shows a cross-sectional view of a light-emitting diode 450 that utilizes photonic crystals 150B, 150C and 150D as well as micro-guide 140 and micro-lens 150 arrays. Photonic crystal 150C of LEDs 430, 440 and 450 can be expanded to occupy the whole top surface of layer 30b rather than part of it. In addition, it is possible to just have one photonic crystal (either photonic crystal 150C or photonic crystal 150D) in the structure of LEDs 430, 440 and 450 rather than having both of the photonic crystals 150C and 150D together.

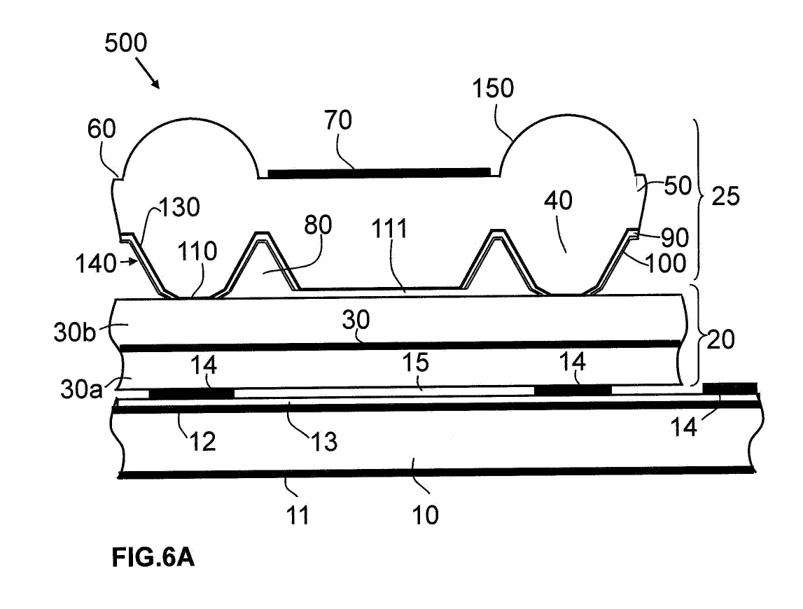

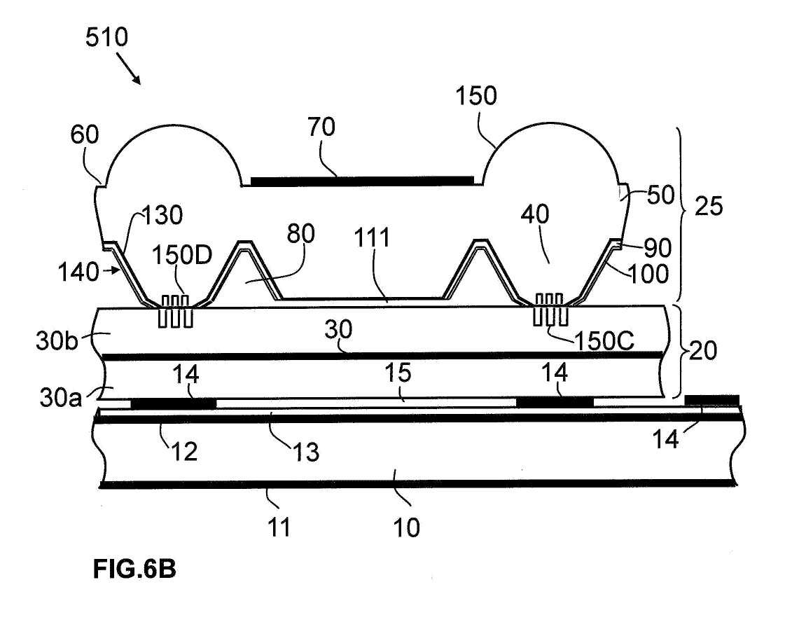

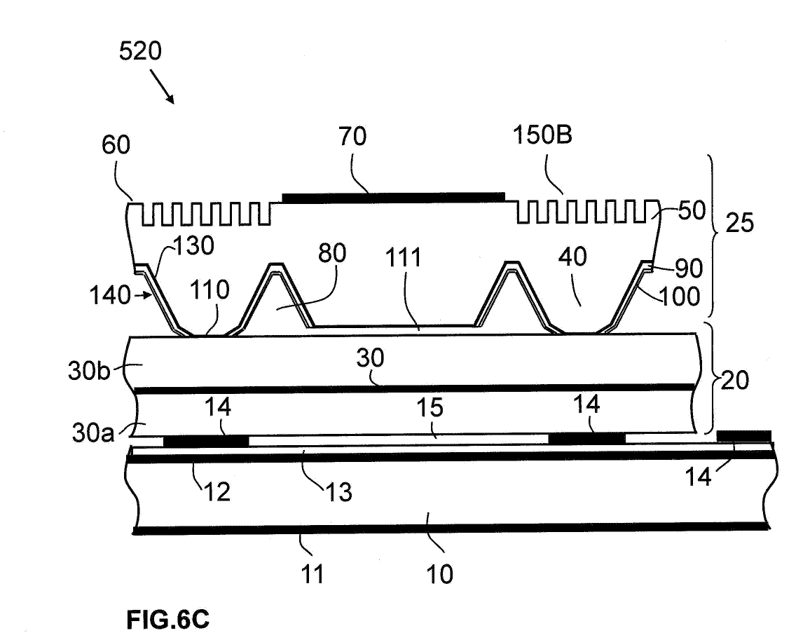

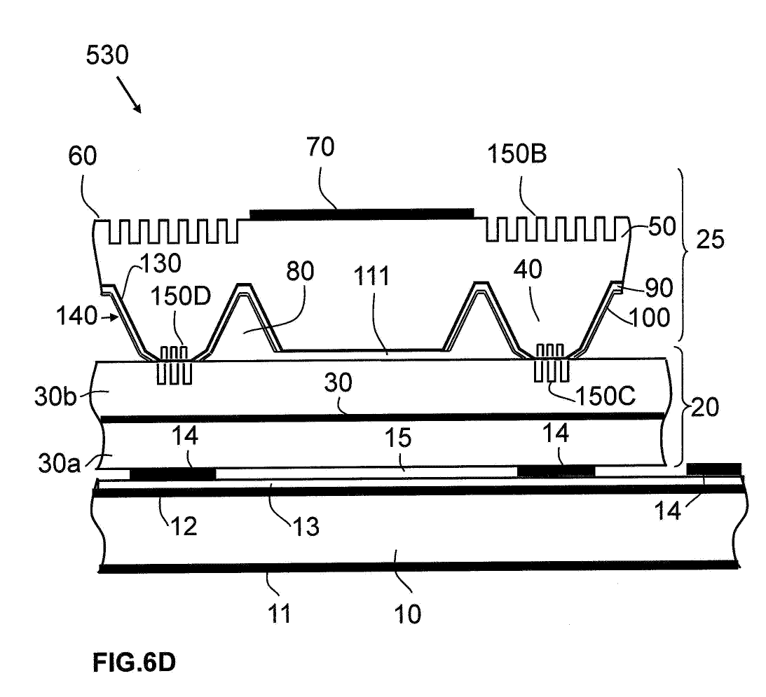

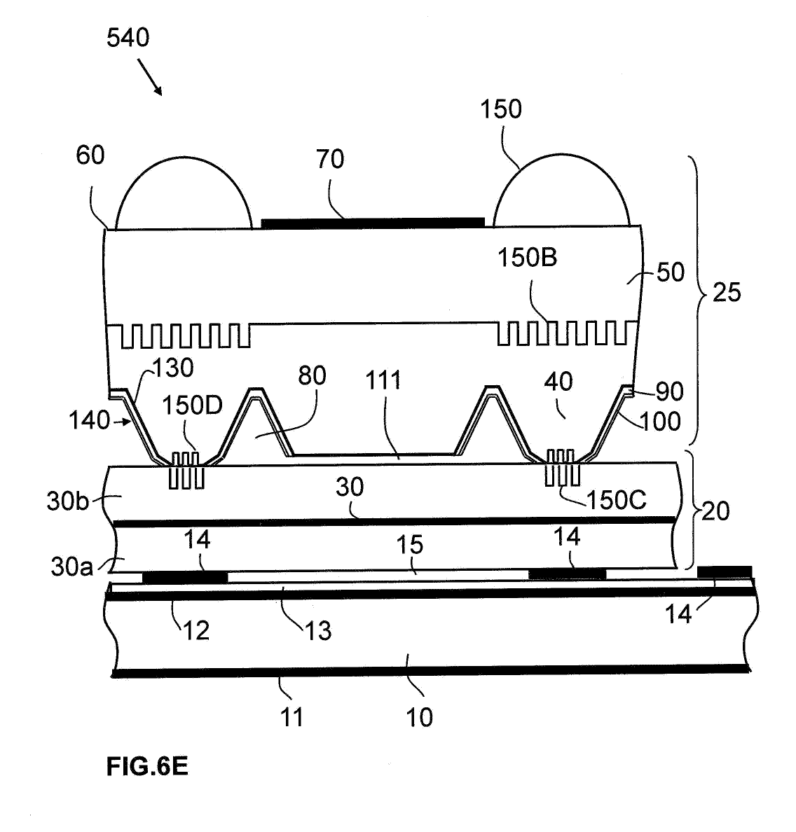

FIG. 6A shows a cross-sectional view of a light-emitting diode 500 that utilizes a micro-element plate 25 for light extraction and a top electrode 70 located at the center of top surface 60 of micro-element plate 25. Micro-element plate 25 consists of a micro-guide array 140 and a corresponding micro-lens array 150. LED 500 requires an interface 110 between plate 25 and epitaxial layer 20 that is optically transparent and has a low-resistance electrical conductance over the entire bonded area. In this case, the current flows between top 70 and bottom 14 electrodes through interface 110. The top electrode 70 is located at the center of the top surface 60 of plate 25 and the bottom electrode is patterned so that the required current flow is obtained. A gap 111 is made in the area that is located directly below the top electrode 70 in order to prevent the current from flowing through that area to the bottom electrode 14, which in turn prevents generating light in such area. Otherwise, most of the light generated in such area will be absorbed by the top electrode 70. FIG. 6B shows a cross-sectional view of a light-emitting diode 510 that utilizes a micro-element plate 25, photonic crystal 150C and optional photonic crystal 150D, and a top electrode 70 located at the center of top surface 60 of micro-element plate 25. FIG. 6C shows a cross-sectional view of a light-emitting diode 520 that utilizes a micro-guide array 140, a photonic crystal 150B at the exit aperture of micro-guide array 140, and a top electrode 70 located at the center of top surface 60 of plate 25. FIG. 6D shows a cross-sectional view of a light-emitting diode 530 that utilizes a micro-guide array 140, photonic crystals 150B, 150C and 150D, and a top electrode 70 located at the center of top surface 60 of plate 25. FIG. 6E shows a cross-sectional view of a light-emitting diode 540 that utilizes a micro-guide array 140, a micro-lens array 150, photonic crystals 150B, 150C and 150D, and a top electrode 70 located at the center of top surface 60 of plate 25. Photonic crystal 150C of LEDs 510, 530 and 540 can be expanded to occupy the whole top surface of layer 30b rather than occupying part of it. In addition, it is possible to just have one photonic crystal (either photonic crystal 150C or photonic crystal 150D) in the structure of LEDs 510, 530 and 540.

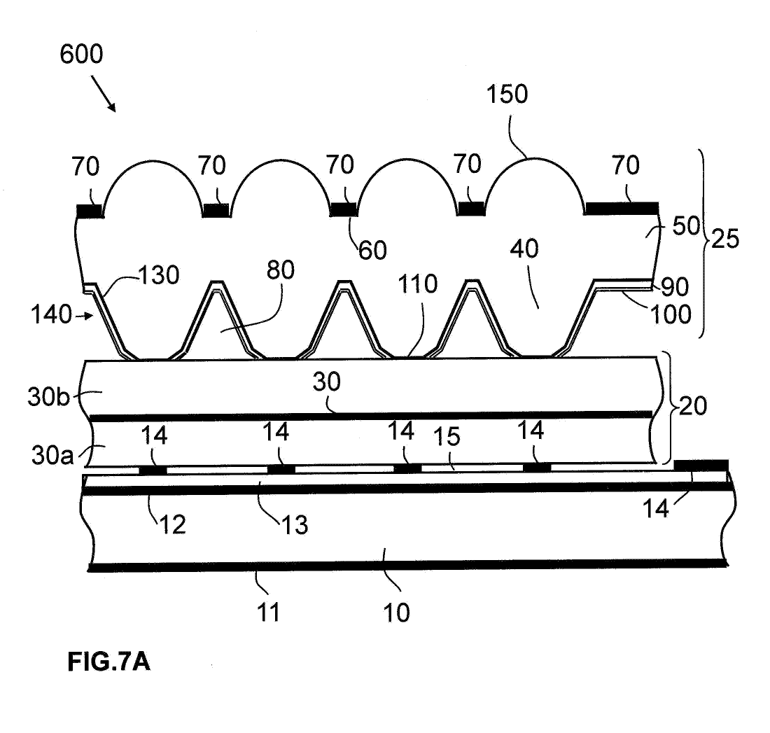

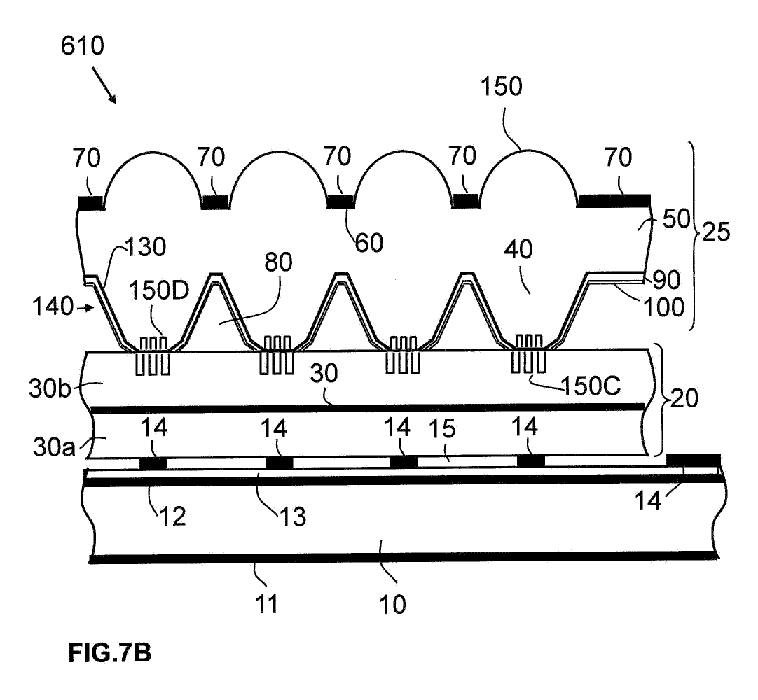

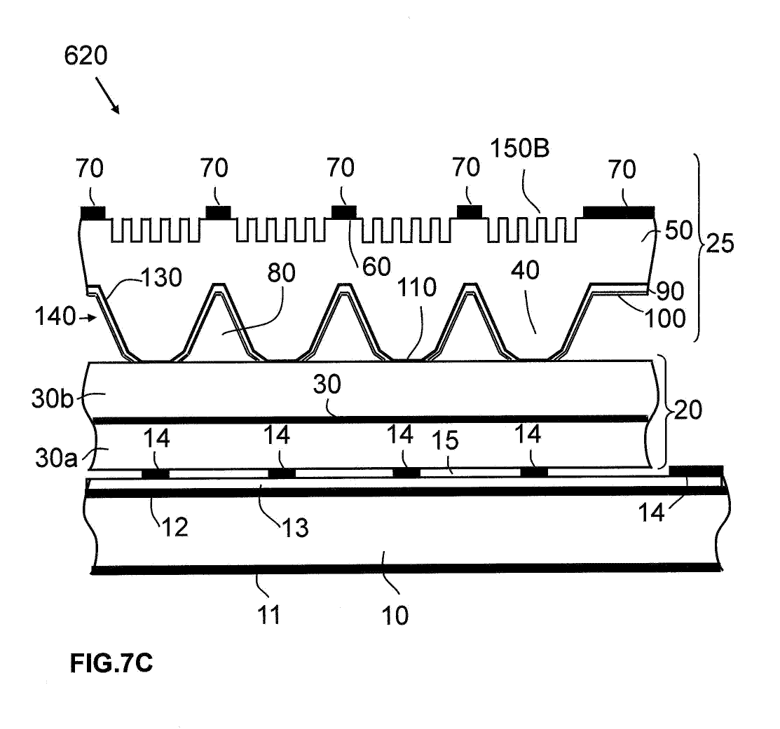

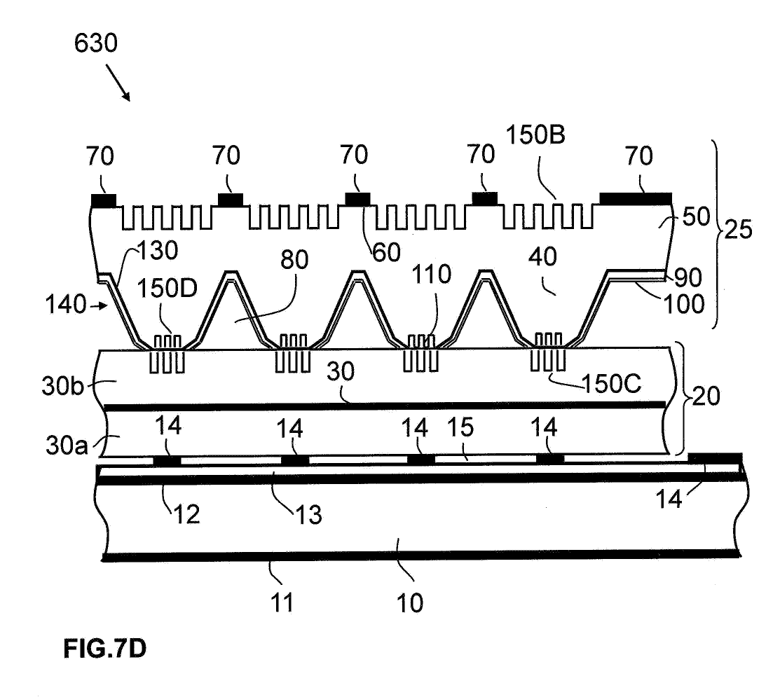

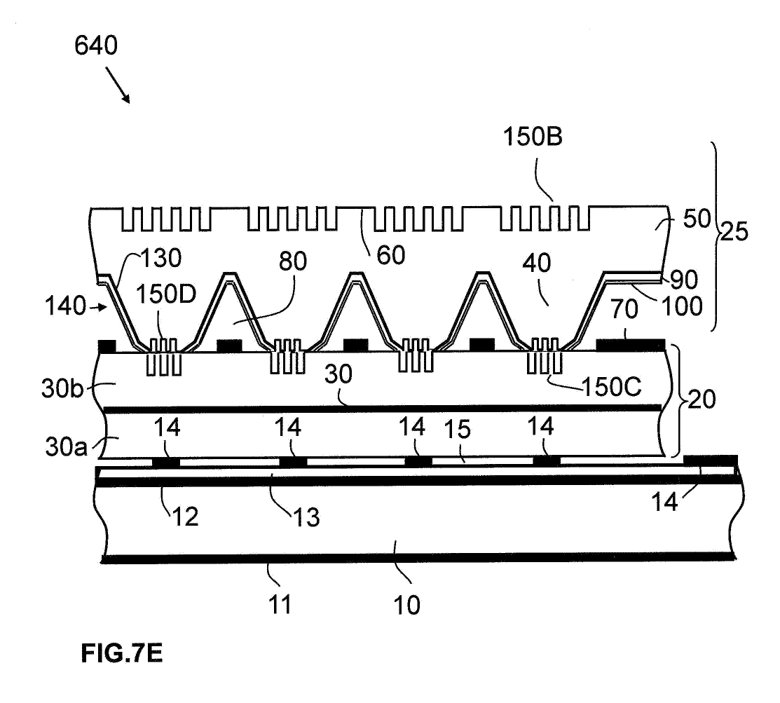

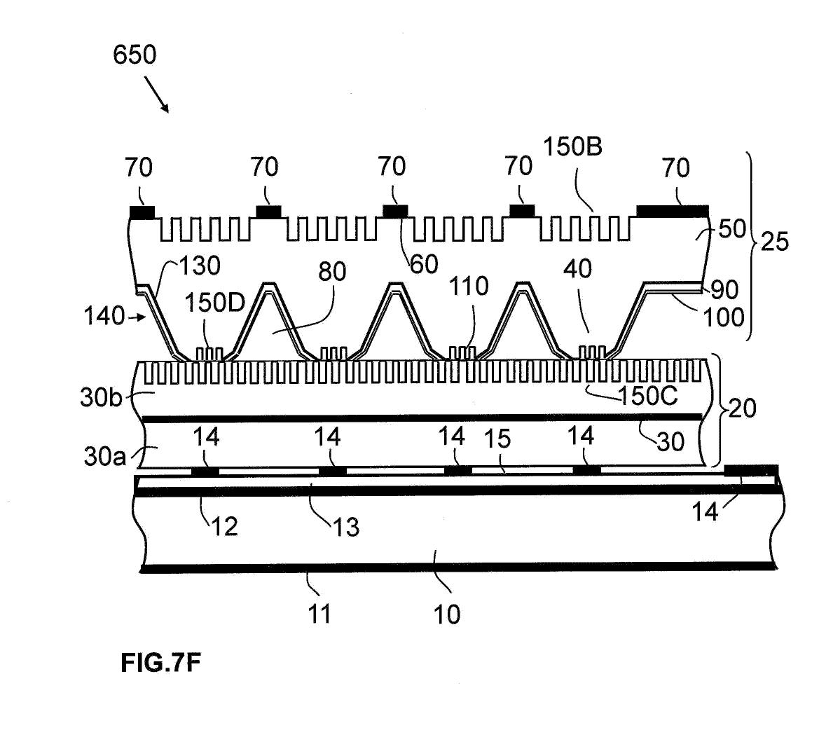

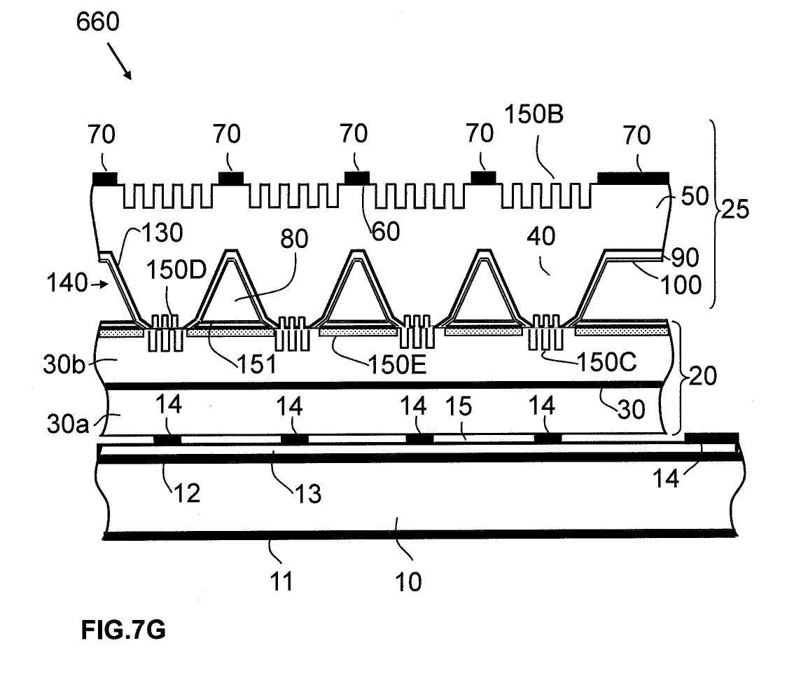

FIG. 7A shows a cross-sectional view of a light-emitting diode 600 that utilizes a micro-element plate 25 for light extraction and a top electrode 70 patterned over the whole top surface 60 of micro-element plate 25. Micro-element plate 25 consists of a micro-guide array 140 and a corresponding micro-lens array 150. The top electrode 70 is deposited in areas located between adjacent micro-lenses of the micro-lens array 150. As the case of LED 500, 510, 520, 530 and 540 of FIGS. 6A-6E, LED 600 also requires an optically transparent and electrically conducting interface 110. FIG. 7B shows a cross-sectional view of a light-emitting diode 610 that utilizes a micro-guide array 140, a micro-lens array 150, photonic crystals 150C and 150D, and a top electrode 70 patterned over top surface of plate 25. FIG. 7C shows a cross-sectional view of a light-emitting diode 620 that utilizes a micro-guide array 140, a photonic crystal 150B at the exit aperture of micro-guide array 140, and a top electrode 70 patterned over top surface of plate 25. FIG. 7D shows a cross-sectional view of a light-emitting diode 630 that utilizes a micro-guide array 140, photonic crystals 150B, 150C and 150D, and a top electrode 70 patterned over top surface of plate 25. FIG. 7E shows a cross-sectional view of a light-emitting diode 640 that utilizes a micro-guide array 140, a micro-lens array 150, photonic crystals 150B, 150C and 150D, and a top electrode 70 patterned over top surface of layer 20. FIG. 7F shows a cross-sectional view of a light-emitting diode 650 that utilizes a micro-guide array 140, photonic crystals 150B, 150C and 150D, and a top electrode 70 patterned over top surface of plate 25. In this case, photonic crystal 150C extends over the whole surface of layer 30b. FIG. 7G shows a cross-sectional view of a light-emitting diode 660 that utilizes a micro-guide array 140, photonic crystal 150C and 150D, a diffusive layer 150E covering the whole surface of layer 30b except the entrance apertures of the micro-guides of micro-guide array 140, and a top electrode 70 patterned over top surface of plate 25. The diffusive layer 150E has an optional highly reflective mirror 151 on its top surface. Optional mirror 151 can be dielectric mirror, distributed Bragg reflector (DBR), omnidirectional reflector (ODR), a metallic mirror or a combination of two or more of these types. The diffusive layer 150E can be made in the top surface of layer 30b using, for example, nanotexturing by natural lithography. Photonic crystal 150C of LEDs 610, 630 and 640 can be expanded to occupy more area of the top surface of layer 30b. In addition, it is possible to just have one photonic crystal (either photonic crystal 150C or photonic crystal 150D) in the structure of LEDs 610, 630, 640 and 650 rather than having both of the photonic crystals 150C and 150D together.

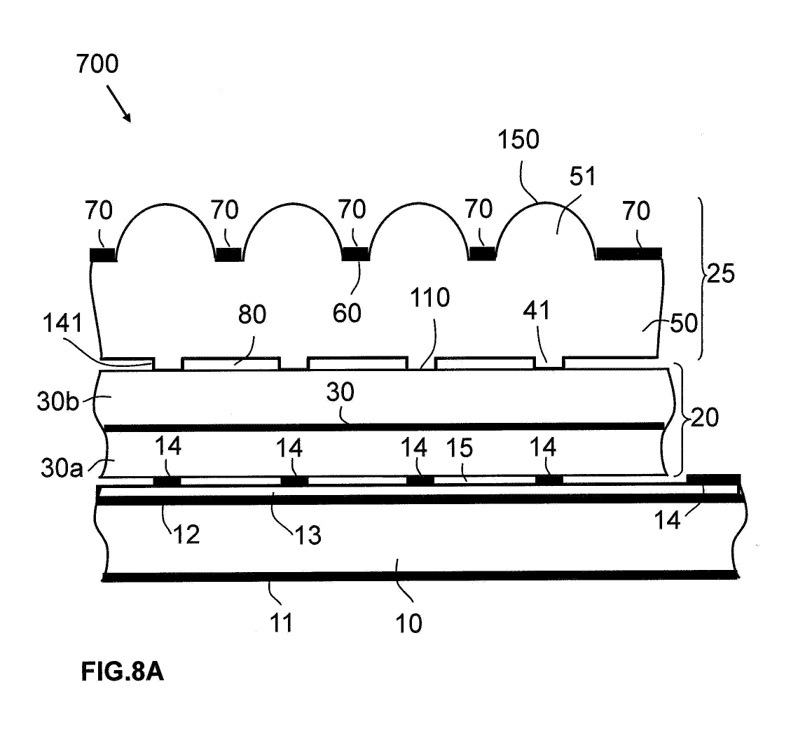

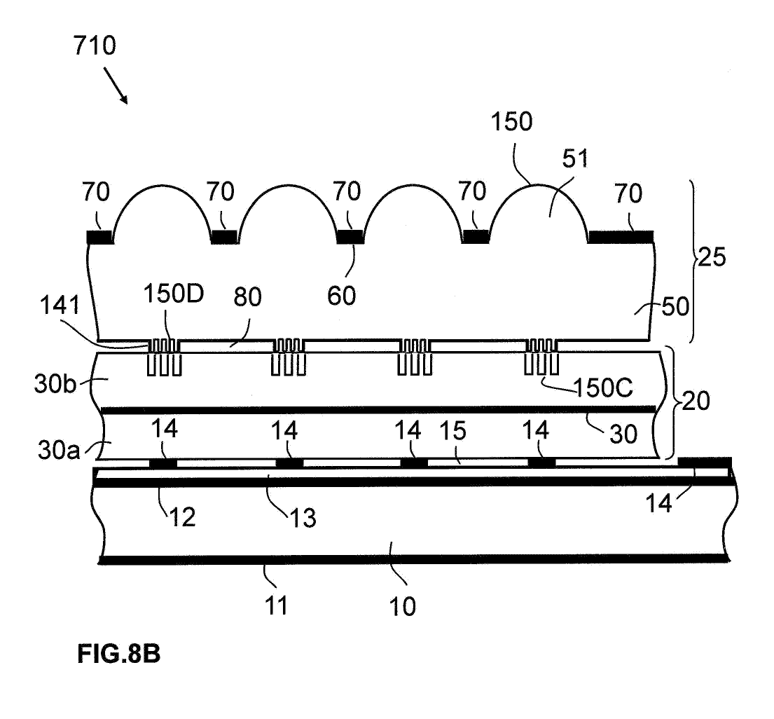

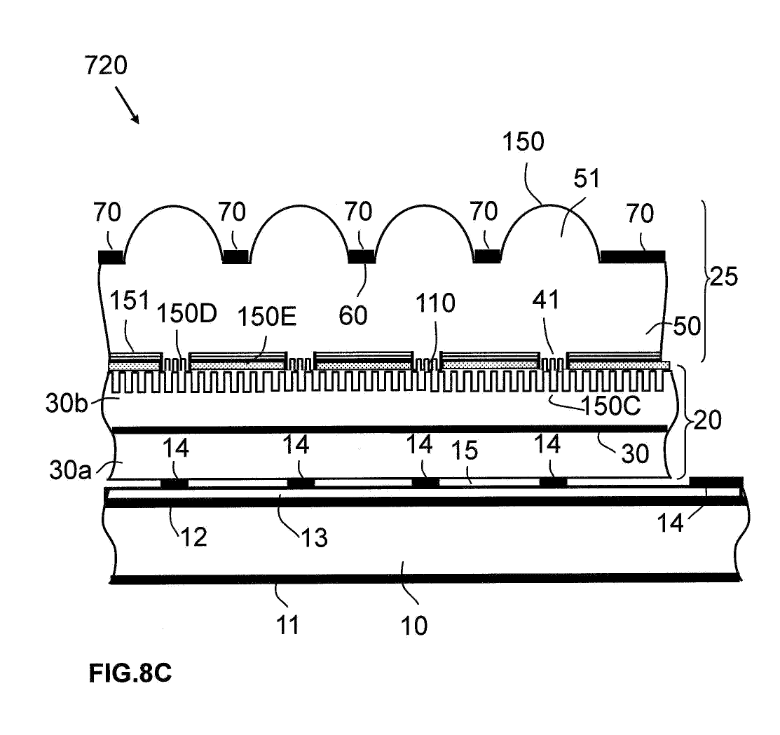

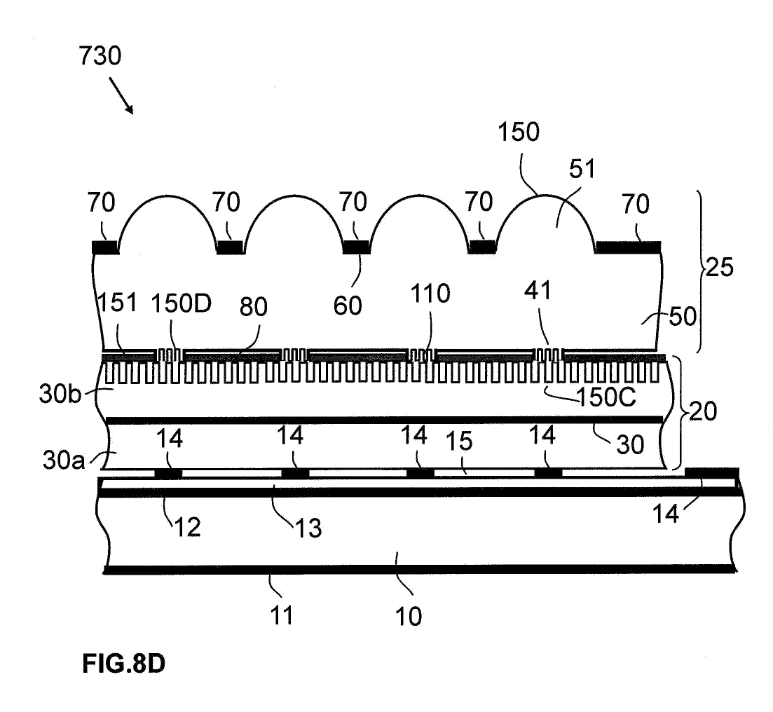

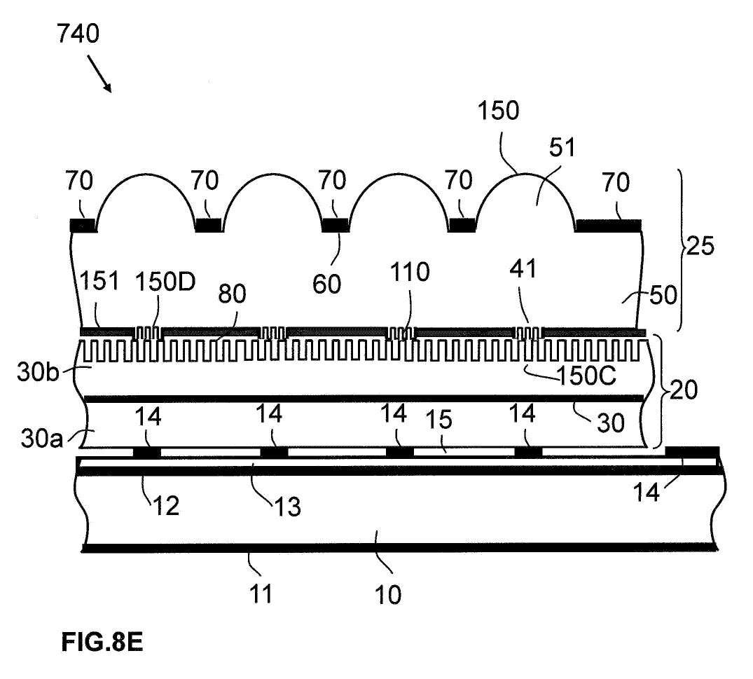

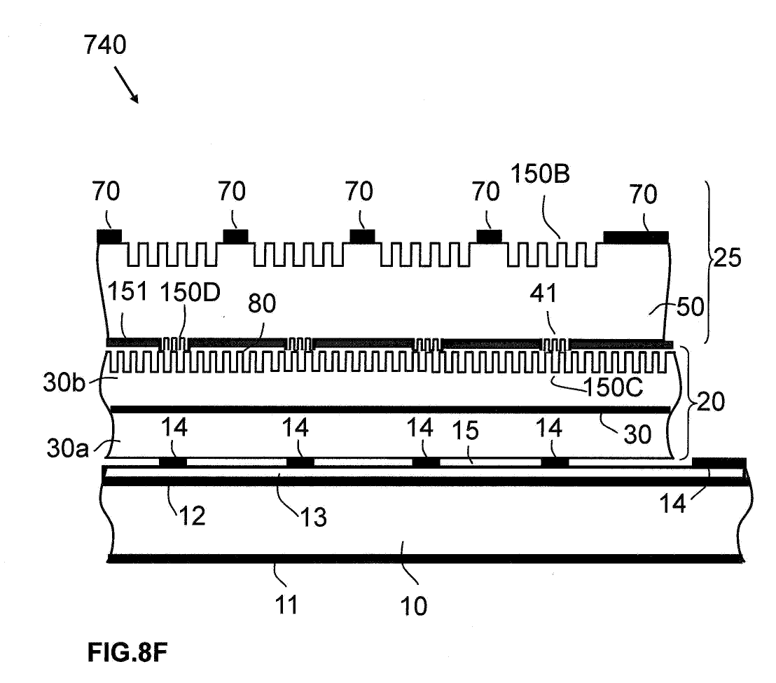

FIG. 8A shows a cross-sectional view of a light-emitting diode 700 that utilizes a micro-element plate 25 for light extraction and a top electrode 70 patterned over the whole top surface 60 of micro-element plate 25. Micro-element plate 25 consists of an array 141 of mesas 41 and a corresponding micro-lens array 150. Adjacent mesas 41 are separated by cavities 80. The mesas 41 can have a cross-sectional shape (in the plane perpendicular to the drawing of FIG. 8) such as circular, square, oval, irregular or any other shape. The cross-sectional area of a mesa 41 is preferably 5%-35% the cross-sectional area (at surface 60) of a micro-lens 51 of micro-lens array 150. The height of a mesa 41 is preferably very small compared to the height of a micro-guide array 140. For example, the mesa 41 cross-sectional area can be 5 μm×5 μm square area with a height of 0.5 μm and the micro-lens 51 cross-sectional area at surface 60 can be 10 μm×10 μm assuming a square micro-lens 51. The purpose of mesa 41 is to couple light from the epitaxial layer 20 into the micro-lens 51 of micro-lens array 150. As shown in FIG. 8A, the top electrode 70 is deposited in areas located between adjacent micro-lenses 51 of the micro-lens array 150. LED 700 also requires an optically transparent and electrically conducting interface 110. FIG. 8B shows a cross-sectional view of a light-emitting diode 710 that utilizes a micro-lens array 150, photonic crystal 150C, optional photonic crystal 150D, and a top electrode 70 patterned over top surface of plate 25. FIG. 8C shows a cross-sectional view of a light-emitting diode 720 that utilizes a micro-lens array 150, optional photonic crystals 150C and 150D, a diffusive layer 150E covering the whole surface of layer 30b except the entrance apertures of the mesas 41, and a top electrode 70 patterned over top surface of plate 25. The diffusive layer 150E has an optional highly reflective mirror 151 on its top surface. Optional mirror 151 can be dielectric mirror, distributed Bragg reflector (DBR), omnidirectional reflector (ODR), a metallic mirror or a combination of two or more of these types. The diffusive layer 150E can be made in the top surface of layer 30b using, for example, nanotexturing by natural lithography. FIG. 8D shows a cross-sectional view of a light-emitting diode 730 that utilizes a micro-lens array 150, photonic crystal 150C, optional photonic crystal 150D, a mirror 151 covering the whole surface of layer 30b of plate 20 except the entrance apertures of the mesas 41, and a top electrode 70 patterned over top surface of plate 25. A gap 80 made of low refractive index material such as air exists between mirror 151 and plate 25. As shown in FIG. 8E, LED 740 has mirror 151 deposited on bottom surface of plate 25 except the mesas 41 rather than being deposited on plate 20 (FIG. 8D). In this case, gap 80 is present between plate 20 and mirror 151. As shown in FIG. 8F, the micro-lens array 150 of FIG. 8E is replaced by photonic crystal 150B. In the same manner, the micro-lens array 150 of FIGS. 8A-8D can be replaced by a photonic crystal 150B.

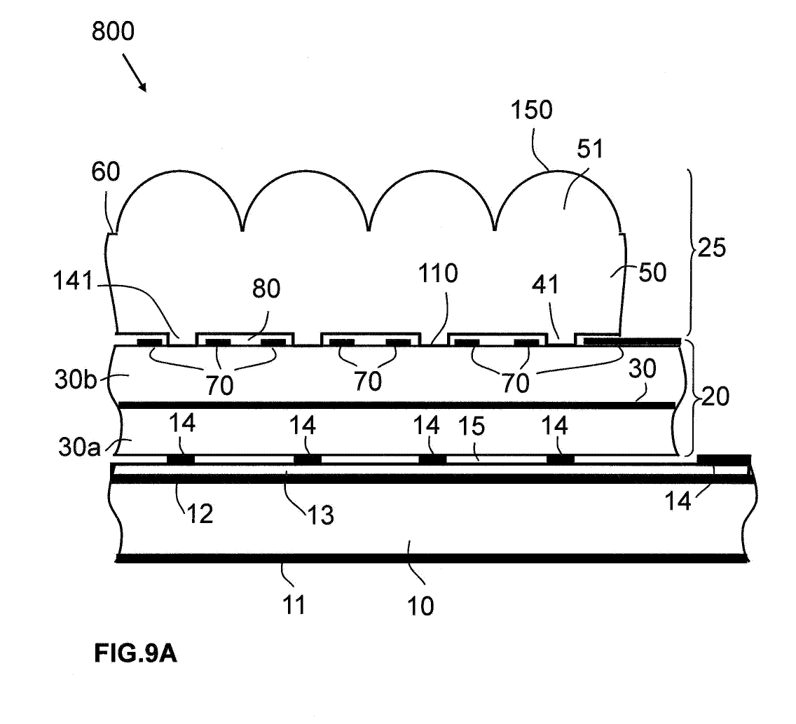

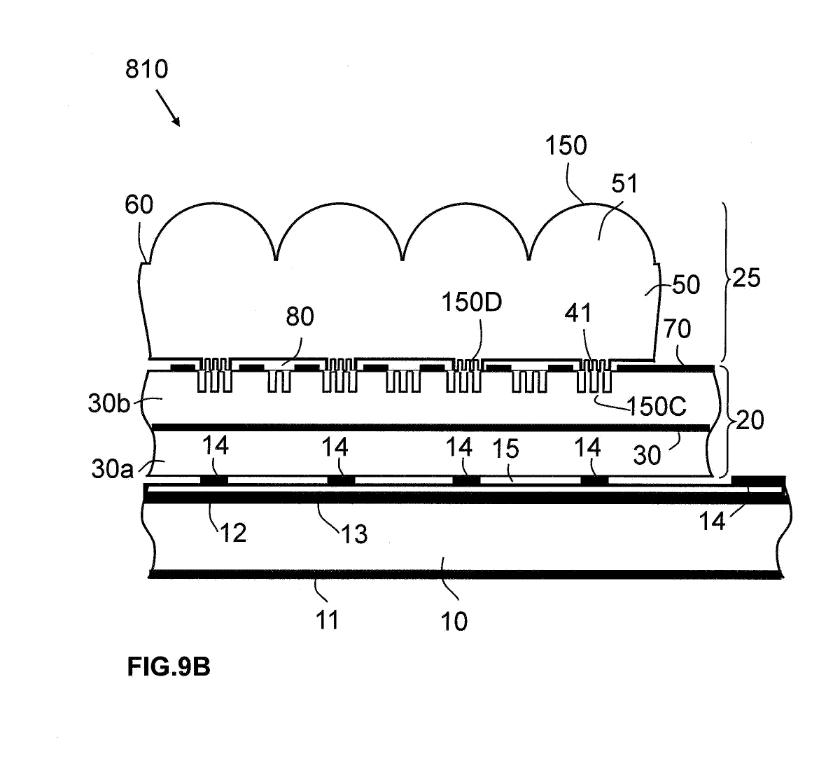

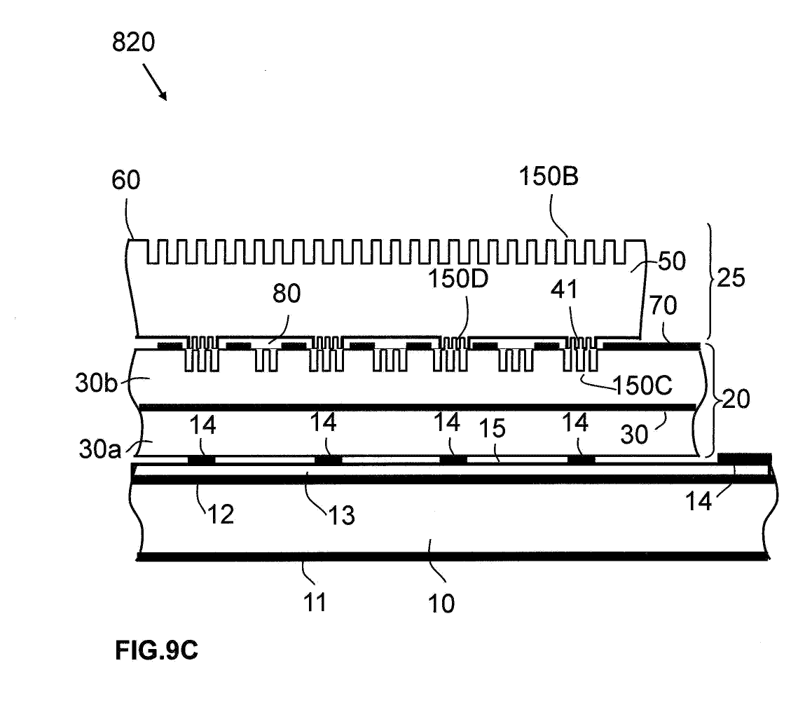

FIG. 9A shows a cross-sectional view of a light-emitting diode 800 that utilizes a micro-element plate 25 for light extraction and a top electrode 70 patterned over the whole top surface of layer 30b of epitaxial plate 20. Micro-element plate 25 consists of an array 141 of mesas 41 and a corresponding micro-lens array 150. Adjacent mesas 41 are separated by cavities 80. The top electrode 70 can be patterned on the top surface of epitaxial 1 plate 20 in the area surrounding the mesas 41 so that the required current distribution through epitaxial plate 20 is obtained. LED 800 does not require an electrically conducting interface 110, however, it requires an optically transparent one. FIG. 9B shows a cross-sectional view of a light-emitting diode 810 that utilizes a micro-lens array 150, photonic crystal 150C, optional photonic crystal 150D, and a top electrode 70 patterned over whole top surface of layer 30b of epitaxial plate 20. FIG. 9C shows a cross-sectional view of a light-emitting diode 820 that utilizes a photonic crystal 150B, photonic crystal 150C, optional photonic crystal 150D, and a top electrode 70 patterned over whole top surface of layer 30b of epitaxial plate 20.

The manufacturing of light-emitting diodes 400, 410, 420, 430, 440 and 450 starts with growing the epitaxial layer 20 on a base substrate. The epitaxial layer 20 is thereby produced first on a base substrate (not shown in FIG. 5), subsequently, the epitaxial layer 20 is bonded to a carrier substrate 10 using, for example, eutectic bonding, and the base substrate (not shown in FIG. 5) is removed by wet-etching. Prior to bonding, the carrier substrate 10 (e.g. a GaAs substrate wafer) is coated with two ohmic contact layers 11 and 12 (e.g. AuGe layer) on its back and front sides, respectively, and a bonding layer 13 (e.g. gold-tin solder layer with appropriate diffusion barriers) on top of contact layer 12. An optional photonic crystal 150C is then made into the top side of layer 20 using suitable wet-chemical or dry-chemical etching processes. The top surface of the upper layer 20 is, subsequently, doped with a concentration above 10¹⁸ cm⁻³ in order to assure that it has a good electrical conductivity. Good conductivity of the upper layer 50 is necessary for spreading current across the LED surface. In addition, it is preferable to have an upper layer 20 that is transparent to the light generated in the active layer 30. Subsequently, the contact layer 70 and an optional metal frame that can be used to distribute current across the surface of the upper layer 20 more efficiently are formed on the front side of the upper layer 20. An optional photonic crystal 150D is then made into the top side of a second substrate (or epitaxial layer grown on a base substrate) using suitable wet-chemical or dry-chemical etching processes. Subsequently, a micro-guide array 140 is made into the same side of the second substrate (or epitaxial layer grown on a base substrate). An optional insulating layer 90 is then deposited onto the micro-guides 140 sidewalls. The micro-guide array 140 is then bonded to a layer 20 using, for example, semiconductor to semiconductor bonding (and the base substrate is removed by wet-etching). In case of LED 400, a micro-lens array 150 is then formed on the top surface of layer 25 using suitable wet-chemical or dry-chemical etching processes. In case of LEDs 410, 420, 440 and 450, an optional photonic crystal 150B is then made into the top side of the second substrate (or epitaxial layer grown on a base substrate) using suitable wet-chemical or dry-chemical etching processes. In case of LEDs 420 and 450, a third substrate (or epitaxial layer grown on a base substrate) is bonded to the top side of the second substrate and then thinned to the desired thickness. Subsequently, a micro-lens array 150 is formed on the top surface of the third substrate 50 using suitable wet-chemical or dry-chemical etching processes.

The above manufacturing process can be used as a guideline in the manufacturing of light-emitting diodes of FIGS. 6-9.

The structures of plate 25 (shown in FIGS. 5-9) can also be combined with LED 24 of FIG. 1A. In this case, plate 25 is bonded to layer 18 of LED 24 using semiconductor to semiconductor bonding techniques after the deposition of contact pads 19a and 19b. Layer 18 of LED 24 can have an optional photonic crystal 10 spreading across its surface. The bonding temperature should be low enough that it does not negatively impact contacts 19a and 19b or mirror 14. Mirror 14 can be distributed Bragg reflector (DBR), omnidirectional reflector (ODR), dielectric mirror, metallic mirror or a combination of two or more of these types. The optional encapsulant material 20 (or epoxy) can be added to the top surface of plate 25 after the bonding process. Subsequently, the cover slip 22 and supports 21 are attached to the combined structure of plate 25 and LED 24.

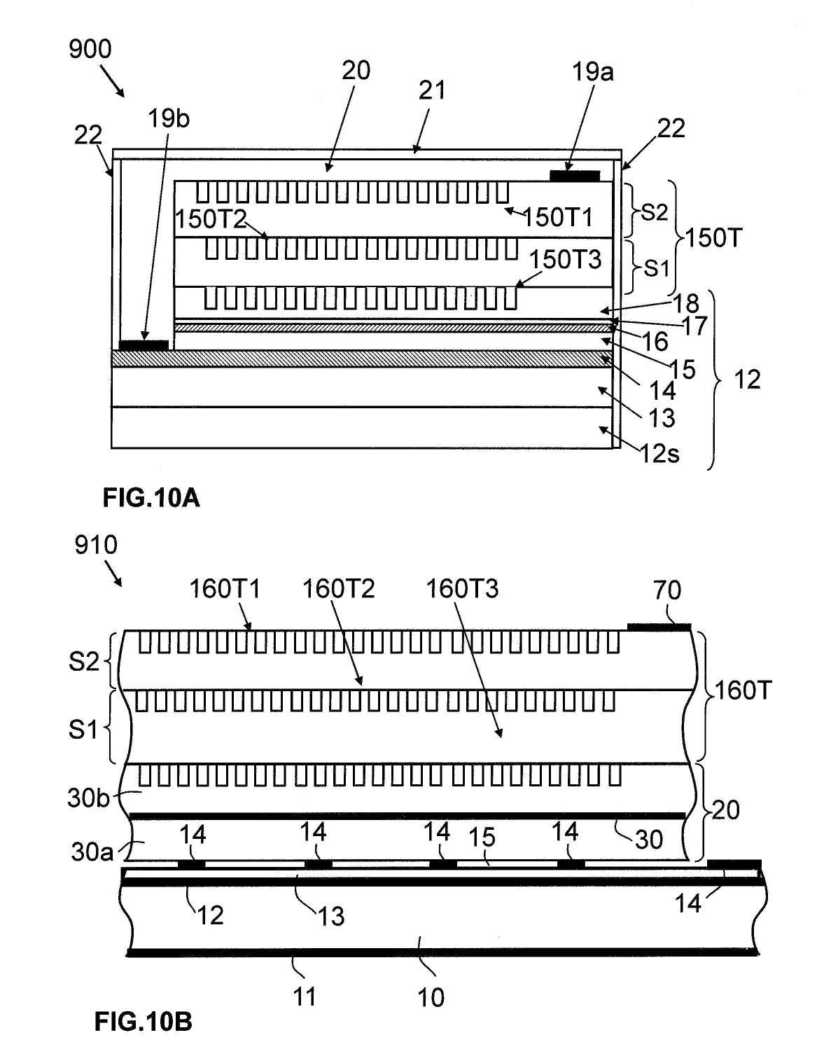

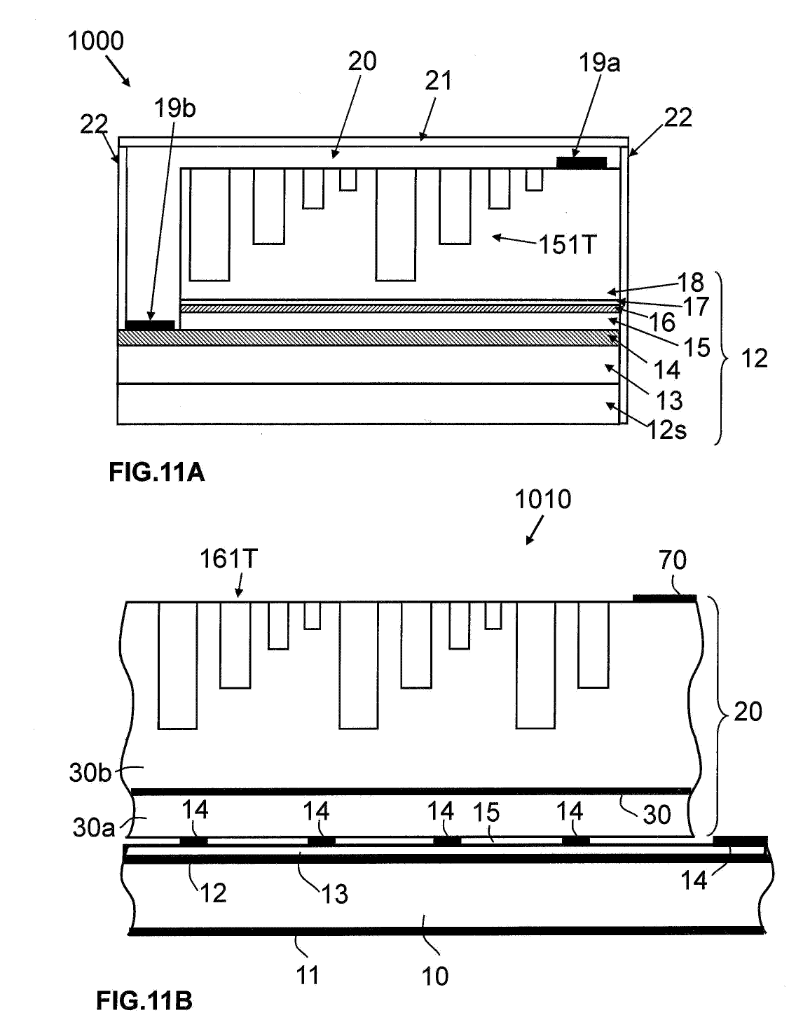

FIG. 10A-10B show cross-sectional views of light-emitting diode 900 and 910 that utilize three dimensional photonic crystals 150T and 160T for light extraction. Three dimensional photonic crystal 150T (and 160T) consists of three 2-dimensional photonic crystals 150T1, 150T2 and 150T3 (and 160T1, 160T2 and 160T3). In general, a three dimensional photonic crystal consists of two or more 2-dimensional photonic crystals. The structure of LED 900 and 910 except the three dimensional photonic crystal 150T and 160T has been discussed earlier. Mirror 14 of FIG. 10A can be distributed Bragg reflector (DBR), omnidirectional reflector (ODR), dielectric mirror, metallic mirror or a combination of two or more of these types. FIGS. 11A and 11B show cross-sectional views of light-emitting diodes 1000 and 1010 that utilize three dimensional photonic crystals 151T and 161T with various opening sizes in terms of separation, depth and diameter. The advantage of this type of three dimensional photonic crystals 151T and 161T is ease of manufacturing. The openings are patterned in a single step and then etched in a single step. Since the openings have various diameters, their etch rate and depth will be different. Openings with larger diameters usually etch faster than ones with smaller diameters leading to a unique three dimensional pattern. The manufacturing of light-emitting diodes 900 is described by Erchak et al. in U.S. Pat. No. 6,831,302 B2, which is incorporated herein by reference. The manufacturing process of a three dimensional photonic crystal 150T (and 160T) starts with making a first 2-dimensional photonic crystal 150T3 on the top side of layer 18. Subsequently, a first substrate S1 is bonded to layer 18. The first substrate S1 is then thinned to the selected thickness using appropriate polishing, dry and/or wet etching techniques. A second 2-dimensional photonic crystal 150T2 is then made on the top side of the first substrate S1. Subsequently, a second substrate S2 is bonded to first substrate S1 and then thinned to a selected thickness. A third 2-dimensional photonic crystal 150T1 is then made on the top side of the first substrate S2.

The manufacturing of light-emitting diodes 910 and 1010 starts with growing the epitaxial layer 20 on a base substrate. The epitaxial layer 20 can, for example, be made on the basis of InGaAlP. The epitaxial layer 20 is thereby produced first on a base substrate (not shown in FIG. 10B), subsequently, epitaxial layer 20 is then bonded or attached to a carrier substrate 10 using, for example, eutectic bonding, and the base substrate (not shown in FIG. 10B) is removed by wet-etching. Prior to bonding, the carrier substrate 10 (e.g. a GaAs substrate wafer) is coated with two ohmic contact layers 11 and 12 (e.g. AuGe layer) on its back and front sides, respectively, and a bonding layer 13 (e.g. gold-tin solder layer with appropriate diffusion barriers) on top of contact layer 12. After the bonding, a first 2-dimensional photonic crystal 160T3 (or 3-dimensional photonic crystal 161T in case of LED 1010 of FIG. 1B) on the top side of layer 30b is made. Subsequently, a first substrate S1 is bonded to layer 30b. The first substrate S1 is then thinned to the selected thickness using appropriate polishing, dry and/or wet etching techniques. A second 2-dimensional photonic crystal 160T2 is then made on the top side of the first substrate S1. Subsequently, a second substrate S2 is bonded to first substrate S1 and then thinned to a selected thickness. A third 2-dimensional photonic crystal 160T1 is then made on the top side of the first substrate S2. The top surface of substrate S2 is, subsequently, doped with a concentration above 10¹⁸ cm⁻³ in order to assure that it has a good electrical conductivity. Good conductivity of the upper thinned substrate S2 is necessary for spreading current across the LED surface 910. In addition, it is preferable to have substrate S1 and substrate S2 that are transparent to the light generated in the active layer 30. Subsequently, the contact layer 70 and an optional metal frame that can be used to distribute current across the top surface of substrate S2 more efficiently are formed on the front side of the of substrate S2.

The three dimensional photonic crystal 150T, 160T, 151T and 161T can be applied to all the LED structures of this disclosure replacing the 2-dimensional photonic crystal.

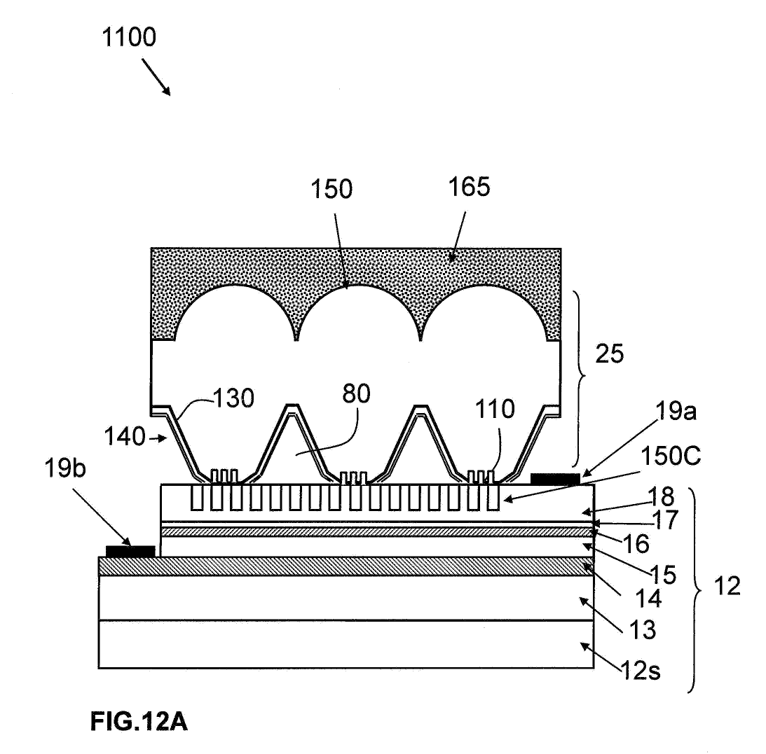

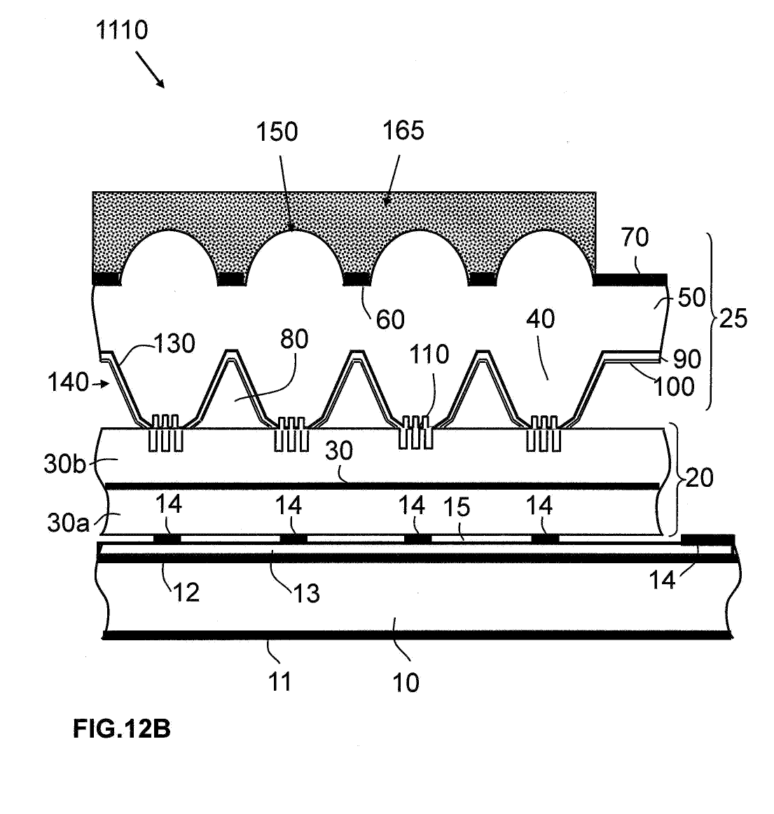

FIG. 12A-12B show cross-sectional views of light-emitting diode 1100 and 1110 that utilize a phosphor layer 165 on top of plate 25. The phosphor material usually interacts with light at the wavelengths generated by region 16 and 30 to provide light at a different set of wavelengths. A phosphor layer 165 such as (Y,Gd)(Al,Ga)G:Ce³⁺ or “YAG” (yttrium, aluminum, garnet) phosphor layer can emit light with a broad spectrum centered around yellow wavelengths when pumped by blue light emitted from the light-generating region 16 and 30. The blue and yellow beams mix together to produce white light. Other phosphor materials such as a phosphor that generates green light when pumped by blue light can be used.

In order to enhance the thermal performance of LED 200, 300, 400, 410, 420, 430, 440, 450, 500, 510, 520, 530, 540, 600, 610, 620, 630, 640, 650, 660, 1100, 1110, cavities 80 can be filled with a material having a high thermal conductivity. Such material permits further heat dissipation through the top surface of the LED resulting in enhanced thermal and optical performances.

In some cases, hollow micro-tunnels are used instead of solid micro-guides 40 of array 140. Such micro-tunnels can be filled with a high refractive index material, thus, allowing more light to enter the filled micro-tunnels compared to the hollow ones. Plates with micro-tunnel arrays are described in U.S. Pat. No. 7,306,344 to Abu-Ageel, which is hereby incorporated by reference.

In some cases, insulating 90 and metal 100 layers deposited on the sidewalls of the micro-guides of array 140 can be removed without having serious performance problems. The micro-guides 40 of array 140 can be of the concave type such as micro-guides 5A, 5B and 5C of FIG. 1B-1D. In addition, micro-guide array 140 and micro-lens array 150 of this disclosure can be of the one dimensional type rather than the two dimensional type. Such types of one-dimensional arrays allow the extraction and collimation of light along one dimension.

Design parameters of each micro/nano-element (e.g., micro-guide, nano-guide, micro-lens, nano-lens, nano-tunnel or micro-tunnel) include shape and size of entrance and exit apertures, depth, sidewalls shape and taper, and orientation. Micro/nano-elements within an array can have uniform, non-uniform, random or non-random distributions and range from one micro/nano-element to millions with each micro/nano-element being distinct in its design parameters. The size of the entrance/exit aperture of each micro-element is preferably ≧5 μm in case of visible light in order to avoid light diffraction phenomenon. However, it is possible to design micro/nano-elements with sizes of entrance/exit aperture being <5 μm. In such case, the design should consider the diffraction phenomenon and behavior of light at such scales to provide control over cone angle and deliver homogeneous light distributions in terms of intensity, viewing angle and color over a certain area. Such micro/nano-elements can be arranged as a one-dimensional array, two-dimensional array, circular array and can be aligned or oriented individually. In addition, the micro/nano-element plate can have a size equal or smaller than the size of the emitting surface of the LED and its shape can be rectangular, square, circular or any other arbitrary shape.

The operation of the micro-element (or extraction plate) is described as follows. Part of the light impinging on the micro-element plate enters through the openings of the aperture array and the remainder is reflected back by total internal reflection (TIR) toward the LED. Light that impinges on areas (surrounding the mesas 41 or entrance apertures of the micro-guides 40) that are coated with a highly reflective coating gets reflected back into the LED. Some of the reflected light gets absorbed and lost within the LED, some gets absorbed and regenerated with a different angle, and the remainder gets reflected back toward the micro-element by a reflective coating formed on the bottom side of the LED and/or TIR depending on the LED structure. This process continues until all the light is either absorbed or transmitted through the micro-element (or extraction plate). Light received by the micro-guide array experiences total internal reflection (or specular reflection) within the micro-guides and becomes highly collimated as it exits the micro-guide array. This collimated light exits the micro-lens array via refraction as a more collimated light. In addition to increasing the amount of light extracted, micro-element (or extraction plate) provides control over the distribution of delivered light in terms of intensity and cone angle at the location of each micro-element. The optional photonic crystal embedded within the micro-element plate (or within the epitaxial layer of the LED) allows the extraction of more light at lower cone angles.

LEDs of this disclosure are applicable to semiconductor light-emitting devices of various materials systems, which include organic semiconductor materials, silicon as well as III-V systems such as III-nitride, III-phosphide, and III-arsenide, and II-VI systems. Examples of light-generating materials include InGaAsP, AlInGaN, AlGaAs, and InGaAlP. Organic light-emitting materials include small molecules such as aluminum tris-8-hydroxyquinoline (Alq₃) and conjugated polymers such as poly[2-methoxy-5-(2-ethylhexyloxy)-1,4-vinylenephenylene] or MEH-PPV. In addition, LEDs of this disclosure are applicable to any semiconductor light-emitting devices that have both contacts formed on the same side of the device (which include, for example, flip-chip and epitaxy-up devices) and devices that have its contacts formed on opposite sides of the device.

Advantages of the LEDs and extraction systems described herein include simple manufacturing which is highly independent of the LED manufacturing, enhanced extraction efficiency without adding complexity to the LED design and fabrication, and providing control over the spatial distribution of emitted light in terms of angle and intensity.

Other embodiments and modifications will occur readily to those of ordinary skill in the art in view of these teachings. Therefore, the following claims are intended to cover all such embodiments and modifications when viewed in conjunction with the above specification and accompanying drawings.

What is claimed is:

1. A light-emitting diode (LED), comprising:
an active layer for emitting light; and
an array of optical micro-elements configured to receive light emitted from the active layer.

2. The LED of claim 1, wherein the array of optical elements includes:
at least one convex-shaped light guide.

3. The LED of claim 2, wherein the active layer passes within the convex-shaped light guide.

4. The LED of claim 2, wherein the active layer is located below a lower side of the convex-shaped light guide.

5. The LED of claim 2, wherein the convex-shaped light guide includes a curved sidewall.

6. The LED of claim 2, wherein the convex-shaped light guide includes two sidewall segments, each formed at a different angle relative to a predetermined axis.

7. The LED of claim 2, wherein the convex-shaped light guide includes three sidewall segments, each formed at a different angle relative to a predetermined axis.

8. The LED of claim 2, further comprising a lens having a diameter equivalent to the diameter of the convex-shaped light guide and configured to receive light exiting the convex-shaped light guide.

9. The LED of claim 2, further comprising:
photonic crystals formed at an input aperture of the convex-shaped light guide.

10. The LED of claim 1, further comprising:
an epitaxial layer; and
a plurality of photonic crystals formed in the epitaxial layer.

11. The LED of claim 1, further comprising electrical contacts formed at the entrance aperture of at least one of the optical micro-elements.

12. The LED of claim 1, wherein the array of optical micro-elements includes:
a first layer of photonic crystals configured to receive light from the active layer; and
a second layer of photonic crystals configured to receive light from the first layer of photonic crystals.

13. The LED of claim 12, wherein the array of optical elements further includes:
an array of lens configured to receive light exiting from the second layer of photonic crystals.

14. The LED of claim 12, wherein the array of optical elements further includes:
a third layer of photonic crystals configured to receive light from the second layer of photonic crystals.

15. A light-emitting diode (LED), comprising:
an active layer for emitting light;
an array convex-shaped light guides configured to receive light emitted from the active layer; and
a layer of photonic crystals configured to receive light exiting the array of convex-shaped light guides.

16. The LED of claim 15, further comprising:
an array of lens having a one-to-one correspondence with the convex-shaped light guides, configured to receive light emitted from the layer of photonic crystals.

17. The LED of claim 15, further comprising:
photonic crystals formed at the entrance aperture of each of the convex-shaped light guides.

18. The LED of claim 15, further comprising:
an electrode formed between the convex-shaped light guides.

19. The LED of claim 18, wherein the electrode is formed on an exterior surface of the LED.

20. The LED of claim 15, further comprising:
a first group of photonic crystals formed at an entrance aperture of each convex-shaped light guide; and
a second group of photonic crystals formed at the entrance aperture of each convex-shaped light guide, the second group of photonic crystals configured to receive light from the first group of photonic crystals.
